(19) United States
(12) Patent Application Publication
(10) Pub. No.: US 2025/0344388 A1
(43) Pub. Date: Nov. 6, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Minkyu CHUNG, Suwon-si (KR); Jongseon AHN, Suwon-si (KR); Sangjae LEE, Suwon-si (KR); Seiwoong PARK, Suwon-si (KR)

(21) Appl. No.: 18/918,441

(22) Filed: Oct. 17, 2024

(30) Foreign Application Priority Data
May 3, 2024 (KR) 10-2024-0059217

(51) Int. Cl. H10B 43/27; H10B 41/27

(52) U.S. Cl. CPC H10B 43/27; H10B 41/27

(57) ABSTRACT

A semiconductor device includes a first stack structure disposed on an upper surface of a substrate and comprising a first recess area disposed on a connection area of the substrate, a second stack structure disposed on the first stack structure and comprising a second recess area disposed on the connection area, a first capping pattern disposed on the first recess area, a second capping pattern disposed on the second recess area, wherein the first recess area comprises a first gate pad area and a first planar area connected with each other, the second recess area comprises a second gate pad area, and at least a portion of the second gate pad area overlaps the first planar area in a vertical direction, and gate contact plugs extending lengthwise in the vertical direction and penetrating the first planar area of the first recess area and the second gate pad area.

### CROSS-REFERENCE TO RELATED APPLICATION

This application claims priority to Korean Patent Application No. 10-2024-0059217, filed in the Korean Intellectual Property Office on May 3, 2024, the entire contents of which are hereby incorporated by reference.

### BACKGROUND

### Field

The present disclosure relates to a semiconductor device and an electronic system including the same.

### Description of Related Art

There is a demand for a semiconductor device capable of storing high-capacity data in an electronic system that requires data storage. Accordingly, the ways to increase the data storage capacity of semiconductor devices are being studied. For example, as one of the methods for increasing the data storage capacity of the semiconductor device, a semiconductor device has been proposed, which includes three-dimensional arrangement of memory cells instead of two-dimensional arrangement of memory cells.

The information described above is intended to improve understanding of the background of the present disclosure, and may include information that does not constitute the related art.

### SUMMARY

In order to solve one or more problems (e.g., the problems described above and/or other problems not explicitly described herein)), the present disclosure provides a reliable semiconductor device capable of increasing an integration density.

The present disclosure also provides an electronic system including the semiconductor device.

An object to be achieved by the present disclosure is not limited to the above, and other objects not mentioned may be clearly understood by those skilled in the art from the description of the present disclosure.

According to an aspect of the present disclosure, a semiconductor device includes a semiconductor substrate comprising a memory cell array area and a connection area, wherein the connection area is adjacent to the memory cell array area in a first horizontal direction parallel to an upper surface of the semiconductor substrate, a first stack structure disposed on the upper surface of the semiconductor substrate and comprising a plurality of first insulating layers and a plurality of first gate layers, which are alternately stacked on each other in a vertical direction perpendicular to the upper surface of the semiconductor substrate and disposed on the memory cell array area and the connection area, the first stack structure comprising a first recess area disposed on the connection area, a second stack structure disposed on the first stack structure and comprising a plurality of second insulating layers and a plurality of second gate layers, which are alternately stacked on each other, the second stack structure comprising a second recess area disposed on the connection area, a first capping pattern disposed on the first recess area, a second capping pattern disposed on the second recess area, wherein the first recess area comprises a first gate pad area and a first planar area which are connected with each other, the second recess area comprises a second gate pad area, and at least a portion of the second gate pad area overlaps the first planar area in the vertical direction, and a plurality of gate contact plugs extending lengthwise in the vertical direction and penetrating the first planar area of the first recess area and the second gate pad area.

According to an aspect of the present disclosure, a semiconductor device includes a semiconductor substrate comprising a memory cell array area and a connection area, wherein the connection area is adjacent to the memory cell array area in a first horizontal direction parallel to an upper surface of the semiconductor substrate, a first structure on the memory cell array area and the connection area, a second structure on the first structure in a vertical direction perpendicular to the upper surface of the semiconductor substrate, a third structure on the second structure in the vertical direction, a vertical memory structure disposed on the memory cell array area, wherein the vertical memory structure extends lengthwise in the vertical direction and penetrates the first structure, the second structure, and the third structure, and a plurality of gate contact plugs disposed on the connection area, wherein the plurality of gate contact plugs extend in the vertical direction and penetrate the first structure, the second structure, and the third structure. The first structure comprises a first stack structure comprising a plurality of first insulating layers and a plurality of first gate wiring layers, which are alternately stacked on each other in the vertical direction, and a first buffer capping pattern penetrating at least a portion of the first stack structure. The second structure comprises a second stack structure comprising a plurality of second insulating layers and a plurality of second gate wiring layers, which are alternately stacked on each other in the vertical direction, a second pad capping pattern penetrating at least a portion of the second stack structure, and a second buffer capping pattern penetrating at least a portion of the second stack structure and connected to the second pad capping pattern. The third structure comprises a third stack structure comprising a plurality of third insulating layers and a plurality of third gate wiring layers, which are alternately stacked on each other in the vertical direction, and a third pad capping pattern penetrating at least a portion of the third stack structure. The plurality of second gate wiring layers comprise a plurality of second gate pads covered by the second pad capping pattern. The plurality of third gate wiring layers comprise a plurality of third gate pads covered by the third pad capping pattern. At least a portion of the second pad capping pattern overlaps the first buffer capping pattern in the vertical direction. At least a portion of the third pad capping pattern overlaps the second buffer capping pattern in the vertical direction.

According to an aspect of the present disclosure, an electronic system includes a main substrate, a semiconductor device on the main substrate, and a controller disposed on the main substrate and electrically connected to the semiconductor device. The semiconductor device comprises a semiconductor substrate comprising a memory cell array area and a connection area, wherein the connection area is adjacent to the memory cell array area in a first horizontal direction parallel to an upper surface of the semiconductor substrate, a first stack structure disposed on the upper surface of the semiconductor substrate and comprising a plurality of first insulating layers and a plurality of first gate layers, which are alternately stacked on each other in a vertical direction perpendicular to the upper surface of the semiconductor substrate and disposed on the memory cell array area and the connection area, the first stack structure comprising a first recess area disposed on the connection area, a second stack structure disposed on the first stack structure and comprising a plurality of second insulating layers and a plurality of second gate layers, which are alternately stacked on each other, the second stack structure comprising a second recess area disposed on the connection area, a first capping pattern disposed on the first recess area, a second capping pattern disposed on the second recess area, wherein the first recess area comprises a first gate pad area and a first planar area which are integrally formed with each other, the second recess area comprises a second gate pad area, and at least a portion of the second gate pad area overlaps the first planar area in the vertical direction, and a plurality of gate contact plugs extending lengthwise in the vertical direction and penetrating the first planar area of the first recess area and the second gate pad area.

According to various aspects of the present disclosure, the lower or intermediate structure of the plurality of vertically stacked structures may include a buffer capping pattern, and some of the plurality of gate contact plugs penetrating the plurality of structures may penetrate the buffer capping pattern. Each of the plurality of structures may include a plurality of gate layers and a plurality of insulating layers, which are alternately stacked on each other, and the plurality of gate contact plugs may be electrically connected to the plurality of gate pads of the plurality of gate layers. The buffer capping pattern can increase reliability of the plurality of gate contact plugs penetrating the plurality of structures. Accordingly, it is possible to increase the integration density and provide a reliable semiconductor device.

According to various aspects of the present disclosure, the pad capping pattern and the buffer capping pattern may be integrally formed, so that the extension length of the connection area associated with the memory cell array area of the semiconductor device can be reduced. Accordingly, the semiconductor device, or the electronic system including the same according to various aspects of the present disclosure can have reduced size.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

FIG. 1 is a top view conceptually illustrating an example of a semiconductor device;

FIG. 2 is a cross-sectional view conceptually illustrating an area taken along line I-I′ of FIG. 1;

FIG. 3 is a cross-sectional view conceptually illustrating an area taken along line II-II′ of FIG. 1;

FIG. 4 is a partially enlarged view of areas denoted as ‘Ba’ and ‘Bb’ of FIG. 3;

FIG. 5 is a partially enlarged view of areas denoted by ‘Aa’ of FIG. 2;

FIG. 6 is a cross-sectional view conceptually illustrating an area taken along line I-I′ of FIG. 1;

FIG. 7 is a partial enlarged view of an area denoted by ‘Ca’ in FIG. 6;

FIG. 8 is a partial enlarged view of an area denoted by ‘Cb’ in FIG. 6;

FIG. 9 is a partial enlarged view of an area denoted by ‘Cc’ in FIG. 6;

FIG. 10 is a cross-sectional view conceptually illustrating an area taken along line I-I′ of FIG. 1;

FIG. 11 is a partial enlarged view of an area denoted by ‘Da’ in FIG. 10;

FIG. 12 is a cross-sectional view conceptually illustrating an area taken along line I-I′ of FIG. 1;

FIG. 13 is a partial enlarged view of an area denoted by ‘Ea’ of FIG. 12;

FIGS. 14 to 17 are cross-sectional views each of which conceptually illustrates an area taken along line I-I′ of FIG. 1;

FIG. 18 is a view schematically illustrating a data storage system including a semiconductor device;

FIG. 19 is a perspective view schematically illustrating an electronic system including a semiconductor device;

FIG. 20 is a cross-sectional view schematically illustrating a semiconductor package.

### DETAILED DESCRIPTION

Hereinafter, terms such as “upper,” “intermediate,” “bottom,” etc. may be replaced with other terms such as “first,” “second,” “third,” etc. to describe certain elements of the description. Terms such as “first”, “first lower”, “first intermediate”, “first upper”, “second”, “second lower”, “second intermediate”, “second upper”, “third”, “third lower,” “third intermediate,” “third upper,” etc. may be used to describe various elements, although the elements are not limited by these terms. For example, a “first element” may be referred to as a “second element”. Likewise, a “second lower element” may be referred to as a “first element” and a “second upper element” may be referred to as a “first element.”

The singular forms “a,” “an,” and “the” as used herein are intended to include the plural forms as well, unless the context clearly indicates the singular forms. Further, the plural forms are intended to include the singular forms as well, unless the context clearly indicates the plural forms.

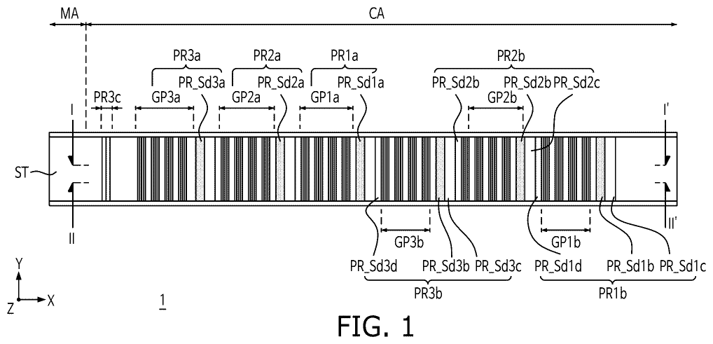

Hereinafter, various aspects of the present disclosure will be described with reference to FIGS. 1 to 20. The same reference numerals may refer to the same components throughout the description.

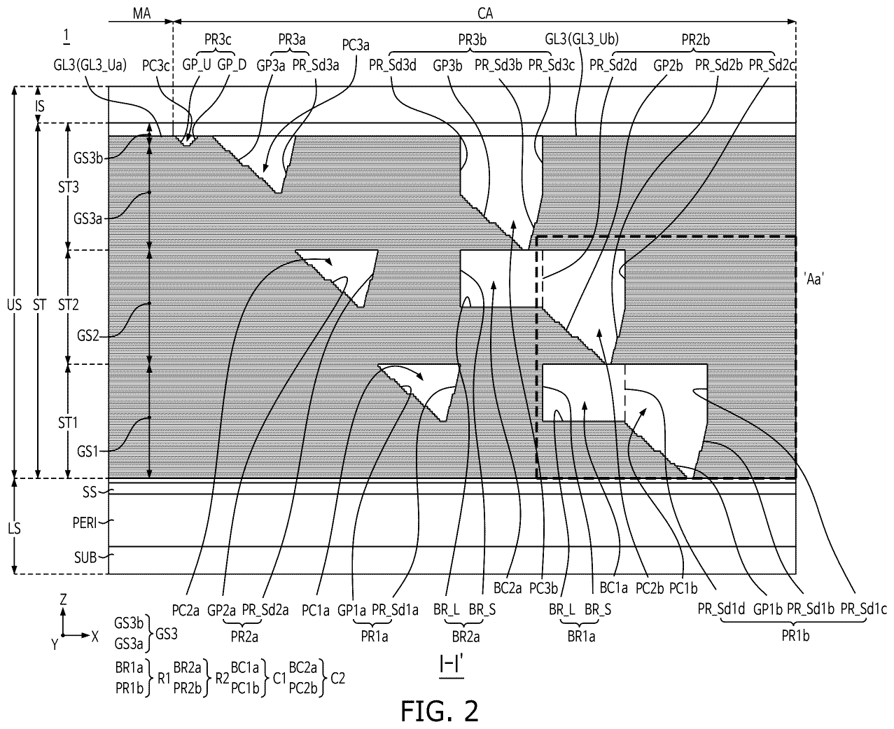

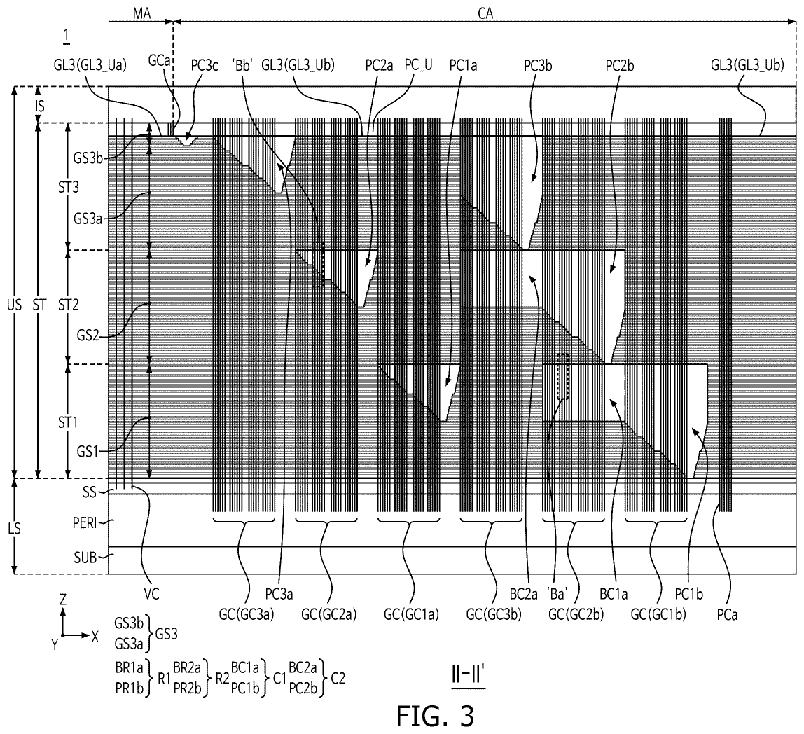

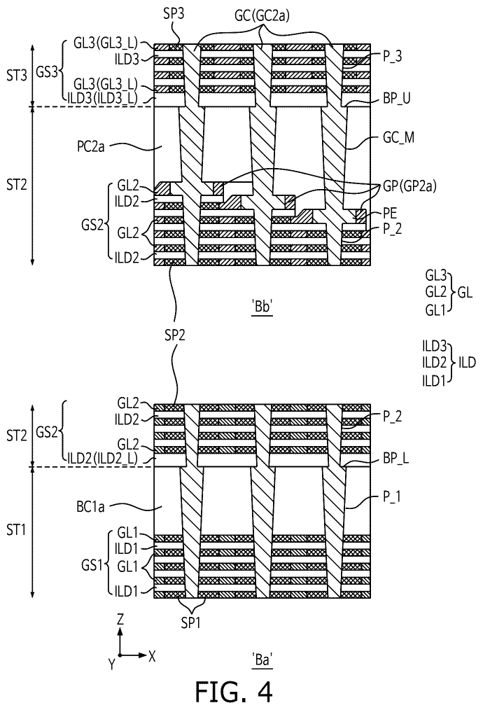

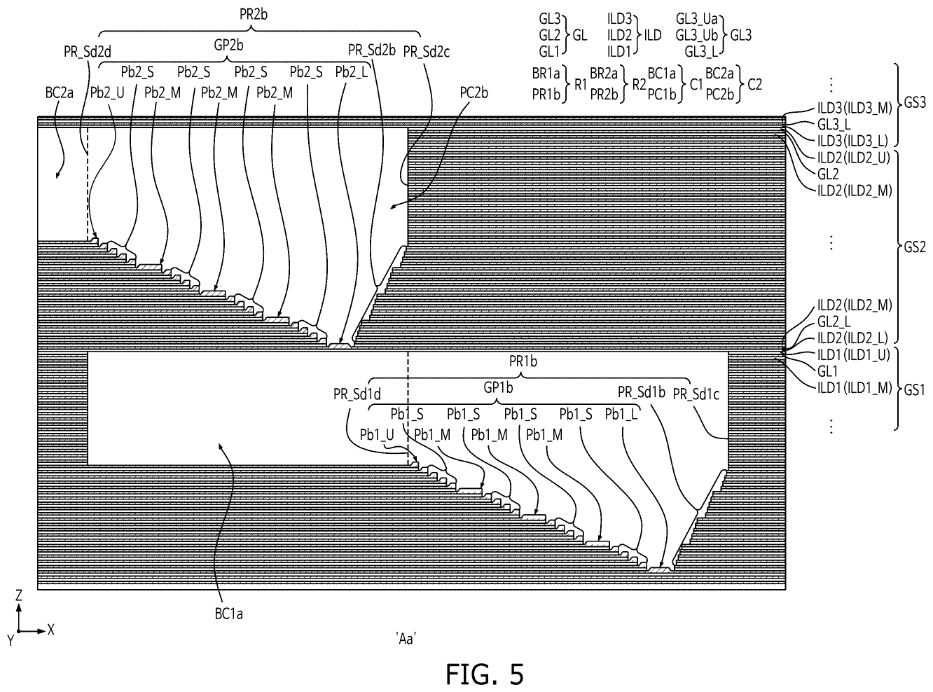

An illustrative example of a semiconductor device will be described with reference to FIGS. 1 to 5. In FIGS. 1 to 5, FIG. 1 is a top view conceptually illustrating an example of a semiconductor device, FIG. 2 is a cross-sectional view conceptually illustrating an area taken along line I-I′ of FIG. 1, FIG. 3 is a cross-sectional view conceptually illustrating an area taken along line II-II′ of FIG. 1, FIG. 4 is a partially enlarged view of areas denoted as ‘Ba’ and ‘Bb’ of FIG. 3, and FIG. 5 is a partially enlarged view of areas denoted by ‘Aa’ of FIG. 2.

A semiconductor device 1 may include a lower structure LS and an upper structure US on the lower structure LS.

The lower structure LS may include a source structure SS. The source structure SS may include polysilicon having an N-type conductivity. For example, the source structure SS may include polysilicon layer doped with N-type dopants.

The lower structure LS may further include a substrate SUB and a peripheral circuit structure PERI on the substrate SUB.

The substrate SUB may be a semiconductor substrate. For example, the substrate SUB may be a semiconductor substrate including single crystal silicon. The peripheral circuit structure PERI may include a peripheral circuit such as a peripheral transistor. The source structure SS may be disposed on the peripheral circuit structure PERI.

The upper structure US may include a plurality of structures ST stacked on each other in a vertical direction Z perpendicular to the upper surface of the substrate SUB, and an upper wiring area IS on the plurality of structures ST.

The semiconductor device 1 may include a memory cell array area MA, and a connection area CA disposed on at least one side of the memory cell array area MA. The memory cell array area MA may be an area in which memory cells storing information are arranged three-dimensionally. The connection area CA may also be referred to as an extension area, a contact area, a pad area, or a stepped area. In an embodiment, the substrate SUB may be divided into the memory cell array MA and the connection area CA which is adjacent to the memory cell array MA in the first horizontal direction X.

The plurality of structures ST may be disposed in the memory cell array area MA and the connection area CA. For example, the plurality of structures ST may be disposed on the memory cell area MA of the substrate ST and the connection area CA thereof.

The plurality of structures ST may include a first structure ST1 and a second structure ST2 on the first structure ST1. The plurality of structures ST may further include a third structure ST3 on the second structure ST2. Aspects are not limited to the above and the plurality of structures ST may include any number of structures which are arranged in the vertical direction Z. For example, the plurality of structures ST may include two structures, or four or more structures. Each of the plurality of structures ST may be formed at any height relative to the upper surface of the substrate SUB in the vertical direction Z. For example, the lowermost structure (e.g., first structure ST1) of the plurality of structures ST1 may be formed to have the highest height.

In the following description, the first structure ST1 is referred to as a lower structure, the second structure ST2 is referred to as an intermediate structure, and the third structure ST3 is referred to as an upper structure. However, depending on the number of structures included in the plurality of structures ST, the intermediate structure may be omitted or a plurality of intermediate structures may be included.

The lower structure ST1 may include a lower stack structure GS1 (i.e., a first stack structure). The intermediate structure ST2 may include an intermediate stack structure GS2 (i.e., a second stack structure). The upper structure ST3 may include an upper stack structure GS3 (i.e., a third stack structure).

The lower stack structure GS1 may include lower interlayer insulating layers ILD1 and lower gate layers GL1, which are alternately stacked on each other in the vertical direction Z. The lower interlayer insulating layers ILD1 may include a lowermost lower interlayer insulating layer, an uppermost lower interlayer insulating layer ILD1_U, and intermediate lower interlayer insulating layers ILD1_M between the lowermost lower interlayer insulating layer and the uppermost lower interlayer insulating layer ILDI_U. The lowermost layer in a stacked structure of the lower interlayer insulating layers ILD1 and the lower gate layers GL1 may be the lowermost lower interlayer insulating layer, and the uppermost layer in the stacked structure of the lower interlayer insulating layers ILD1 and the lower gate layers GL1 may be the uppermost lower interlayer insulating layer ILD1_U.

The intermediate stack structure GS2 may include intermediate interlayer insulating layers ILD2 and intermediate gate layers GL2, which are alternately stacked on each other. The intermediate interlayer insulating layers ILD2 may include a lowermost intermediate interlayer insulating layer ILD2_L, an uppermost intermediate interlayer insulating layer ILD2_U, and intermediate interlayer insulating layers ILD2_M between the lowermost intermediate interlayer insulating layer ILD2_L and the uppermost intermediate interlayer insulating layer ILD2_U. The lowermost layer in a stacked structure of the intermediate interlayer insulating layers ILD2 and the intermediate gate layers GL2 may be the lowermost intermediate interlayer insulating layer ILD2_L, and the uppermost layer in the stacked structure of the intermediate interlayer insulating layers ILD2 and the intermediate gate layers GL2 may be the uppermost intermediate interlayer insulating layer ILD2_U.

The upper stack structure GS3 may include upper interlayer insulating layers ILD3 and upper gate layers GL3, which are alternately stacked on each other. The upper interlayer insulating layers ILD3 may include a lowermost upper interlayer insulating layer ILD3_L, an uppermost upper interlayer insulating layer (not illustrated), and intermediate upper interlayer insulating layers ILD3_M between the lowermost upper interlayer insulating layer ILD3_L and the uppermost upper interlayer insulating layer. The lowermost layer in a stacked structure of the upper interlayer insulating layers ILD3 and the upper gate layers GL3 may be the lowermost upper interlayer insulating layer ILD3_L, and the uppermost layer in the stacked structure of the upper interlayer insulating layers ILD3 and the upper gate layers GL3 may be the uppermost upper interlayer insulating layer.

Each of the lower, intermediate, and upper interlayer insulating layers ILD1, ILD2, and ILD3 may include an insulating material such as silicon oxide.

Each of the lower, intermediate, and upper gate layers GL1, GL2, and GL3 may include a gate electrode. Each of the lower, intermediate, and upper gate layers GL1, GL2, and GL3 may further include a gate dielectric layer covering upper and lower surfaces of the gate electrode and at least a portion of a side surface of the gate electrode. Each of the lower, intermediate, and upper gate layers GL1, GL2, and GL3 may include a gate pad covered by a corresponding pad capping pattern.

A lower recess area R1 may be formed in the lower stack structure GS1. The lower recess area R1 may include a lower pad recess area PR1b and a lower buffer recess area BR1a integrally formed with each other. For example, the lower pad recess area PR1b may be connected to the lower buffer recess area BR1a. The lower stack structure GS1 may include at least one lower pad recess area PR1a and PR1b and at least one lower buffer recess area BR1a. In an embodiment, the lower recess area R1 may correspond to a recess extending from an upper surface of the lower stack structure GS1 toward a lower surface of the lower stack structure GS1. The recess may be formed by removing a portion of the stacked structure which is in the connection area CA.

The at least one lower pad recess area PR1a and PR1b and the at least one lower buffer recess area BR1a may be disposed in the connection area CA.

In the lower stack structure GS1, the at least one lower pad recess area PR1a and PR1b may have an open upper portion. The at least one lower buffer recess area BR1a may have an open upper portion.

The at least one lower pad recess area PR1a and PR1b may include a first lower pad recess area PR1a, and a second lower pad recess area PR1b that is farther away from the memory cell array area MA than the first lower pad recess area PR1a.

The first lower pad recess area PR1a may include a first lower gate pad area GP1a and a first dummy sidewall PR_Sd1a. As used herein, the term “dummy” is used to refer to a component that has the same or similar structure and shape as other components but does not have a substantial function and exists only as a pattern in the device. The second lower pad recess area PR1b may include a second lower gate pad area GP1b and second dummy sidewalls PR_Sd1b and PR_Sd1c. The second lower gate pad area GP1b may be included in one (i.e., the lower gate layer) of the upper and lower gate layers included in the lower gate layers GL1 of the lower stack structure GS1. The upper and lower gate layers may refer to layers divided from the gate layer of the lower stack structure GS1 into an equal height or a predetermined height. For example, the lower gate layers GL1 of the lower stack structure GS1 may be divided into a lower group of gate lines of the lower gate layers GL1 and an upper group of gate lines of the lower gate layers GL1. The second lower gate pad area GP1b may be included in one of the lower and upper groups. In FIG. 2, the second lower gate pad area GP1b is formed in the lower group of the lower gate layers GL1 of the lower stack structure GS1. The upper and lower groups of the lower gate layers GL1 may be grouped to have the same number of gate layers among the lower gate lines GL1. The present disclosure is not limited thereto. For example, the upper and lower groups may have different numbers of gate lines among the lower gate lines GL1.

The first lower gate pad area GP1a may have a shape of stairs that go down by steps at a first average slope in a direction away from the memory cell array area MA. In an embodiment, the stairs of the first lower gate pad area GP1a are formed in an area with a first width in a first horizontal direction X (i.e., a first direction) and a first height in the vertical direction Z, thereby having a first slope obtained by dividing the first height by the first width.

The first dummy sidewall PR_Sd1a may have a shape of stairs that go down by steps at a second average slope greater than the first average slope in the direction toward the memory cell array area MA. The first dummy sidewall PR_Sd1a may have a steeper slope than the first lower gate pad area GP1a. In an embodiment, the stairs of the first dummy sidewall PR_Sd1a are formed in an area with a second width in the first horizontal direction X and a second height in the vertical direction Z, thereby having a second slope obtained by dividing the second height by the second width. The second slope may be greater than the first slope. The first dummy sidewall PR_Sd1a and the first lower gate pad area GP1a may be facing each other and be disposed at substantially the same height level. A distance between the first dummy sidewall PR_Sd1a and the first lower gate pad area GP1a may become narrower from top to bottom.

The second lower gate pad area GP1b may have substantially the same shape of stairs as the first lower gate pad area GP1a. For example, the second lower gate pad area GP1b and the first lower gate pad area GP1a may have the same average slope. The second lower gate pad area GP1b may have a shape of stairs that go down by steps at the first average slope of the first lower gate pad area GP1a in a direction away from the memory cell array area MA.

The second dummy sidewalls PR_Sd1b and PR_Sd1c of the second lower pad recess area PR1b may include a first dummy portion PR_Sd1b and a second dummy portion PR_Sd1c.

The first dummy portion PR_Sd1b may have substantially the same shape as the first dummy sidewall PR_Sd1a. For example, the first dummy portion PR_Sd1b and the first dummy sidewall PR_Sd1a may have the same average slope, thereby having a shape of stairs that go down by steps at the second average slope in the direction toward the memory cell array area MA. The first dummy portion PR_Sd1b may have a steeper slope than the second lower gate pad area GP1b. The first dummy portion PR_Sd1b and the second lower gate pad area GP1b may face each other and be disposed at substantially the same height level. A distance between the first dummy portion PR_Sd1b and the second lower gate pad area GP1b may become narrower from top to bottom.

The second dummy portion PR_Sd1c may be adjacent to the first dummy portion PR_Sd1b and may be disposed at a higher level than the first dummy portion PR_Sd1b, and may have a steeper slope than the slope of the first dummy portion PR_Sd1b. The second dummy portion PR_Sd1c may be formed in the vertical direction Z. For example, the slope of the second dummy portion PR_Sd1c may extend in the vertical direction Z. The second dummy portion PR_Sd1c may be disposed at a level substantially the same as the first dummy sidewall PR_Sd1a.

A lower capping pattern C1 may be disposed in the lower recess area R1. The lower capping pattern C1 may include a first lower buffer capping pattern BC1a and a second lower pad capping pattern PC1b. The first lower buffer capping pattern BC1a and the second lower pad capping pattern PC1b may be integrally formed with each other. Note that a virtual boundary line PR_Sd1d is illustrated between the first lower buffer capping pattern BC1a and the second lower pad capping pattern PC1b, but this is merely for convenience of description and may not refer to an actual separate physical configuration.

The first lower gate pad area GP1a and the second lower gate pad area GP1b may include gate pads of the lower gate layers GL1.

At least one of the first lower gate pad area GP1a or the second lower gate pad area GP1b may include a first upper pad Pb1_U, first stepped pad groups Pb1_S at a lower level than the first upper pad Pb1_U, and one or more first intermediate pads Pb1_M disposed between the first stepped pad groups Pb1_S. At least one of the first lower gate pad area GP1a or the second lower gate pad area GP1b may further include a first lower pad Pb1_L at a level lower than the first stepped pad groups Pb1_S.

The first lower pad Pb1_L of the first lower gate pad area GP1a may be disposed on a bottom surface of the first lower pad recess area PR1a. Likewise, the first lower pad Pb1_L of the second lower gate pad area GP1b may be disposed on a bottom surface of the second lower pad recess area PR1b.

The first stepped pad groups Pb1_S may include gate pads arranged in a shape of stairs. The stairs may go down by steps, and each of the stairs may extend beyond an upper stair in the first horizontal direction X. The first horizontal direction X may be parallel to the upper surface of the substrate SUB and it may be a direction from the memory cell array area MA toward the connection area CA.

The first stepped pad groups Pb1_S may include ‘n’ number of first stepped pad groups, and the one or more first intermediate pads Pb1_M may include ‘n-1’ number of first intermediate pads. ‘n’ may be 2, or a natural number greater than 2. For example, the second lower gate pad area GP1b may include the first upper pad Pb1_U at the topmost and the first lower pad Pb1_L at the bottommost, and may further include the first stepped pad groups Pb1_S and the first intermediate pads Pb1_M therebetween. Each of the first stepped pad groups Pb1_S and each of the first intermediate pads Pb1_M may be alternately arranged between the first upper pad Pb1_U and the first lower pad Pb1_L.

The one or more first intermediate pads Pb1_M may include a plurality of first intermediate pads. Hereinbelow, examples will be described mainly with reference to the plurality of first intermediate pads Pb1_M.

Each of the first intermediate pads Pb1_M may be disposed between the first stepped pad groups Pb1_S adjacent to each other. For example, one first intermediate pad Pb1_M may be disposed between the first stepped pad groups Pb1_S that are adjacent to each other. The width of each of the first intermediate pads Pb1_M in the first horizontal direction X may be greater than the width of each of the gate pads of the first stepped pad groups Pb1_S in the first horizontal direction X.

The at least one lower buffer recess area BR1a may include a first lower buffer recess area BR1a. Aspects are not limited thereto, and the at least one lower buffer recess area BR1a of the first structure ST1 may include a lower buffer recess area vertically overlapping any pad recess area and pad capping pattern in the second structure ST2. For example, the at least one lower buffer recess area BR1a may include a second lower buffer recess area (not illustrated) vertically overlapping the first intermediate pad recess area PR2a and the first intermediate pad capping pattern PC2a. The at least one lower buffer recess area BR1a may have shapes substantially the same as or similar to each other. The at least one lower buffer recess area BR1a may be disposed at the same level as each other.

Each of the at least one lower buffer recess area BR1a may include a bottom surface BR_L and a sidewall BR_S. The bottom surface BR_L may be a planar area that is maintained at a certain height along the first direction X. The sidewall BR_S may be formed in the substantially vertical direction Z. The present disclosure is not limited thereto. In an embodiment, the sidewall BR_S may have a shape of stairs that gradually go down by steps in the direction toward the bottom surface BR_L.

In the at least one lower buffer recess area BR1a, the bottom surface BR_L may be at a higher level than the bottom surface of the first lower pad recess area PR1a.

In the at least one lower buffer recess area BR1a, the bottom surface BR_L may be disposed at a level substantially the same as or similar to that of the uppermost first intermediate pad of the first intermediate pads Pb1_M of the first lower gate pad area GP1a.

In the at least one lower buffer recess area BR1a, the bottom surface BR_L may be disposed at a level of an upper surface of the first upper pad Pb1_U or a level of an upper surface of the uppermost first stepped pad group among the first stepped pad groups Pb1_S. In the at least one lower buffer recess area BR1a, the bottom surface BR_L may be

disposed at a level substantially the same as or similar to that of a point at which the second dummy sidewalls PR_Sd1b and PR_Sd1c are connected with each other.

In each of the at least one lower buffer recess area BR1a, the bottom surface BR_L may be disposed at a level substantially the same as or similar to that of the bottom surface of the first lower pad recess area PR1a.

The lower structure ST1 may further include at least one lower pad capping pattern PC1a and PC1b on the at least one lower pad recess area PR1a and PR1b, and at least one lower buffer capping pattern BC1a on the at least one lower buffer recess area BR1a. The at least one lower pad capping pattern PC1a and PC1b may fill the at least one lower pad recess area PR1a and PR1b (or may be disposed on the gate pad area), and the at least one lower buffer capping pattern BC1a may fill the at least one lower buffer recess area BR1a (or may be disposed on a planar area of the at least one lower buffer recess area BR1a).

The at least one lower pad capping pattern PC1a and PC1b and the at least one lower buffer capping pattern BC1a may be formed of the same insulating material as each other. For example, the at least one lower pad capping pattern PC1a and PC1b and the at least one lower buffer capping pattern BC1a may include an insulating material such as silicon oxide. In an embodiment, the at least one lower pad capping pattern PC1a and PC1b and the at least one lower buffer capping pattern BC1a may be consisted of the same insulating material such as silicon oxide.

The at least one lower pad capping pattern PC1a and PC1b may include a first lower pad capping pattern PC1a formed on the first lower pad recess area PR1a to fill the first lower pad recess area PR1a, and the second lower pad capping pattern PC1b formed on the second lower pad recess area PR1b to fill the second lower pad recess area PR1b.

The maximum thickness of the second lower pad capping pattern PC1b in the vertical direction Z may be greater than the maximum thickness of the first lower pad capping pattern Pc1a in the vertical direction Z.

The at least one lower buffer capping pattern BC1a may include the first lower buffer capping pattern BC1a formed on the first lower buffer recess area BR1a to fill the first lower buffer recess area BR1a. Aspects are not limited thereto, and the at least one lower buffer capping pattern BC1a may further include a second lower buffer capping pattern (not illustrated) formed on the second lower buffer recess area (not illustrated) to fill the second lower buffer recess area (not illustrated).

The at least one lower buffer capping pattern BC1a may have the same thickness as each other. The thickness of each of the at least one lower buffer capping pattern BC1a may be less than or substantially the same as the maximum thickness of the first lower pad capping pattern PC1a in the vertical direction Z.

The intermediate stack structure GS2 may include an intermediate recess area R2. The intermediate recess area R2 may include an intermediate pad recess area PR2b and an intermediate buffer recess area BR2a integrally formed with each other. The intermediate stack structure GS2 may include at least one intermediate pad recess area PR2a and PR2b, and at least one intermediate buffer recess area BR2a.

The at least one intermediate pad recess area PR2a and PR2b and the at least one intermediate buffer recess area BR2a may be disposed in the connection area CA.

In the intermediate stack structure GS2, the at least one intermediate pad recess area PR2a and PR2b may have an open upper portion. The at least one intermediate buffer recess area BR2a may have an open upper portion.

The at least one intermediate pad recess area PR2a and PR2b may include a first intermediate pad recess area PR2a, and a second intermediate pad recess area PR2b that is farther away from the memory cell array area MA than the first intermediate pad recess area PR2a.

The first intermediate pad recess area PR2a may include a first intermediate gate pad area GP2a and a first dummy sidewall PR_Sd2a. The second intermediate pad recess area PR2b may include a second intermediate gate pad area GP2b and second dummy sidewalls PR Sd2b and PR_Sd2c. The second intermediate gate pad area GP2b may be included in one (i.e., the lower gate layer) of the upper and lower gate layers included in the intermediate gate layers GL2 of the intermediate stack structure GS2. The upper and lower gate layers may refer to layers divided from the gate layer of the intermediate stack structure GS2 into an equal height or a predetermined height.

The first intermediate gate pad area GP2a may have a shape of stairs that go down by steps at a substantially same slope as the first lower gate pad area GP1a. For example, the shape of the stairs of the first intermediate gate pad area GP2a may have the first average slope. In an embodiment, the stairs of the first intermediate gate pad area GP2a are formed in an area with the first width in the first horizontal direction X and the height in the vertical direction Z, thereby having the first slope, which is the same as the first slope of the first lower gate pad area GP1a. The first width and the first height of the first intermediate gate pad area GP2a may be the same as the first width and the first height of the first lower gate pad area GP1a.

The first dummy sidewall PR_Sd2a of the first intermediate pad recess area PR2a may have a shape of stairs that go down by steps at substantially the same slope as the first dummy sidewall PR_Sd1a of the first lower pad recess area PR1a. The first dummy sidewall PR_Sd2a may have a steeper slope than the first intermediate gate pad area GP2a. The first dummy sidewall PR_Sd2a and the first intermediate gate pad area GP2a may be facing each other and may be disposed at substantially the same height level. A distance between the first dummy sidewall PR_Sd2a and the first intermediate gate pad area GP2a may become narrower from top to bottom.

The second intermediate gate pad area GP2b may have substantially the same shape of stairs as the first intermediate gate pad area GP2a.

The second dummy sidewalls PR_Sd2b and PR_Sd2c of the second intermediate pad recess area PR2b may include a first dummy portion PR_Sd2b and a second dummy portion PR_Sd2c.

The first dummy portion PR_Sd2b may have substantially the same shape as the first dummy sidewall PR_Sd2a. For example, the first dummy portion PR_Sd2b may have a shape of stairs that go down by steps at the second average slope in the direction toward the memory cell array area MA. The first dummy portion PR_Sd2b may have a steeper slope than the second intermediate gate pad area GP2b. The first dummy portion PR_Sd2b and the second intermediate gate pad area GP2b may face each other and may be disposed at substantially the same height level. A distance between the first dummy portion PR_Sd2b and the second intermediate gate pad area GP2b may become narrower from top to bottom.

The second dummy portion PR_Sd2c may be adjacent to the first dummy portion PR_Sd2b and may be disposed at a higher level than the first dummy portion PR_Sd2b, and may have a steeper slope than the slope of the first dummy portion PR_Sd2b. The second dummy portion PR_Sd2c may be formed in the vertical direction Z. For example, the slope of the second dummy portion PR_Sd2c may extend in the vertical direction Z. The second dummy portion PR_Sd2c may be disposed at a level substantially the same as the first dummy sidewall PR_Sd2a.

An intermediate capping pattern C2 may be disposed in the intermediate recess area R2. The intermediate capping pattern C2 may include a first intermediate buffer capping pattern BC2a and a second intermediate pad capping pattern PC2b. The first intermediate buffer capping pattern BC2a and the second intermediate pad capping pattern PC2b may be integrally formed with each other. Note that a virtual boundary line PR_Sd2d is illustrated between the first intermediate buffer capping pattern BC2a and the second intermediate pad capping pattern PC2b, but this is merely for convenience of description and may not refer to an actual separate physical configuration.

The first intermediate gate pad area GP2a and the second intermediate gate pad area GP2b may include gate pads of the intermediate gate layers GL2.

At least one of the first intermediate gate pad area GP2a or the second intermediate gate pad area GP2b may include a second upper pad Pb2_U, second stepped pad groups Pb2_S at a lower level than the second upper pad Pb2_U, and one or more second intermediate pads Pb2_M disposed between the second stepped pad groups Pb2_S. At least one of the first intermediate gate pad area GP2a and the second intermediate gate pad area GP2b may further include a second lower pad Pb2_L at a lower level than the second stepped pad groups Pb2_S.

The second lower pad Pb2_L of the first intermediate gate pad area GP2a may be disposed on a bottom surface of the first intermediate pad recess area PR2a. Likewise, the second lower pad Pb2_L of the second intermediate gate pad area GP2b may be disposed on a bottom surface of the second intermediate pad recess area PR2b.

The second stepped pad groups Pb2_S may include gate pads arranged in a shape of stairs. The stairs may go down by steps, and each of the stairs may extend beyond an upper stair in the first horizontal direction X.

There may be ‘n’ number of the first stepped pad groups Pb1_S, ‘m’ number of the second stepped pad groups Pb2_S, and ‘m−1’ number of the one or more second intermediate pads Pb2_M.

‘m’ may be a natural number different from ‘n’. For example, ‘m’ may be a natural number less than ‘n’. For example, ‘n’ may be ‘m+1’. For example, ‘4’ first stepped pad groups Pb1_S and ‘3’ second stepped pad groups Pb2_S may be arranged, but aspects are not limited thereto. For example, ‘5’ first stepped pad groups Pb1_S and ‘4’ second stepped pad groups Pb2_S may be arranged. The present disclosure is not limited thereto. In an embodiment, ‘m’ may be a natural number greater than or equal to ‘n’.

The one or more second intermediate pads Pb2_M may include a plurality of second intermediate pads. Hereinbelow, examples will be described mainly with reference to the plurality of second intermediate pads Pb2_M.

Each of the second intermediate pads Pb2_M may be disposed between the second stepped pad groups Pb2_S adjacent to each other. For example, one second intermediate pad Pb2_M may be disposed between the second stepped pad groups Pb2_S adjacent to each other. The width of each of the second intermediate pad Pb2_M in the first horizontal direction X may be greater than the width of each of the gate pads of the second stepped pad groups Pb2_S in the first horizontal direction X.

The at least one intermediate buffer recess area BR2a may be disposed at the same level as each other and may include a first intermediate buffer recess area BR2a. Aspects are not limited thereto, and the at least one intermediate buffer recess area BR2a may include, in the second structure ST2, an intermediate buffer recess area vertically overlapping any pad recess area and the pad capping pattern in the third structure ST3. For example, the at least one intermediate buffer recess area BR2a may include a second intermediate buffer recess area (not illustrated) vertically overlapping the first upper pad recess area PR3a and the first upper pad capping pattern PC3a. The at least one intermediate buffer recess area BR2a may have shapes substantially the same as or similar to each other. The at least one intermediate buffer recess area BR2a may be disposed at the same level as each other.

Each of the at least one intermediate buffer recess area BR2a may include a bottom surface BR_L and a sidewall BR_S. The bottom surface BR_L may be a flat area that is maintained at a certain height along the first direction X. The sidewall BR_S may be formed in the substantially vertical direction Z. The present disclosure is not limited thereto. In an embodiment, the sidewall BR_S may have a shape of stairs that gradually go down by steps in the direction toward the bottom surface BR_L. The bottom surface BR_L and the sidewall BR_S of each of the at least one intermediate buffer recess area BR2a may be formed in substantially the same shape as the bottom surface BR_L and the sidewall BR_S of each of the at least one lower buffer recess area BR1a.

In each of the at least one intermediate buffer recess area BR2a, the bottom surface BR_L may be at a higher level than the bottom surface of the first intermediate pad recess area PR2a.

In each of the at least one intermediate buffer recess area BR2a, the bottom surface BR_L may be disposed at a level substantially the same as or similar to that of the uppermost second intermediate pad of the second intermediate pads Pb2_M of the first intermediate gate pad area GP2a.

In each of the at least one intermediate buffer recess area BR2a, the bottom surface BR_L may be disposed at a level of an upper surface of the second upper pad Pb2_U or a level of an upper surface of the uppermost second stepped pad group among the second stepped pad groups Pb2_S.

In each of the at least one intermediate buffer recess area BR2a, the bottom surface BR_L may be disposed at a level substantially the same as or similar to that of a point at which the second dummy sidewalls PR_Sd2b and PR_Sd2c are connected with each other.

In each of the at least one intermediate buffer recess area BR2a, the bottom surface BR_L may be disposed at a level substantially the same as or similar to that of the bottom surface of the first intermediate pad recess area PR2a.

The intermediate structure ST2 may further include at least one intermediate pad capping pattern PC2a and PC2b on the at least one intermediate pad recess area PR2a and PR2b, and at least one intermediate buffer capping pattern BC2a on the at least one intermediate buffer recess area BR2a.

The at least one intermediate pad capping pattern PC2a and PC2b may fill the at least one intermediate pad recess area PR2a and PR2b (or may be disposed on the gate pad area), and the at least one intermediate buffer capping pattern BC2a may fill the at least one intermediate buffer recess area BR2a (or may be disposed on a planar area of at least one intermediate buffer recess area BR2a).

The at least one intermediate pad capping pattern PC2a and PC2b and the at least one intermediate buffer capping pattern BC2a may be formed of the same insulating material as each other. For example, the at least one intermediate pad capping pattern PC2a and PC2b and the at least one intermediate buffer capping pattern BC2a may include an insulating material such as silicon oxide. In an embodiment, the at least one intermediate pad capping pattern PC2a and PC2b and the at least one intermediate buffer capping pattern BC2a may be consisted of the same insulating material such as silicon oxide.

The at least one intermediate pad capping pattern PC2a and PC2b may include the first intermediate pad capping pattern PC2a formed on the first intermediate pad recess area PR2a to fill the first intermediate pad recess area PR2a, and the second intermediate pad capping pattern PC2b formed on the second intermediate pad recess area PR2b to fill the second intermediate pad recess area PR2b.

The maximum thickness of the second intermediate pad capping pattern PC2b in the vertical direction Z may be greater than the maximum thickness of the first intermediate pad capping pattern PC2a in the vertical direction Z.

The at least one intermediate buffer capping pattern BC2a may include the first intermediate buffer capping pattern BC2a formed on the first intermediate buffer recess area BR2a to fill the first intermediate buffer recess area BR2a. Aspects are not limited thereto, and the at least one intermediate buffer capping pattern BC2a may further include a second intermediate buffer capping pattern (not illustrated) formed on the second intermediate buffer recess area (not illustrated) to fill the second intermediate buffer recess area.

At least one intermediate buffer capping pattern BC2a may have the same thickness as each other. The thickness of each of the at least one intermediate buffer capping pattern BC2a may be less than or substantially the same as the maximum thickness of the first intermediate pad capping pattern PC2a in the vertical direction Z.

The first lower buffer recess area BR1a and the first lower buffer capping pattern BC1a may vertically overlap the second intermediate pad recess area PR2b and the second intermediate pad capping pattern PC2b.

The upper stack structure GS3 may include a first upper stack structure GS3a and a second upper stack structure GS3b on the first upper stack structure GS3a.

The first upper stack structure GS3a may include at least one upper pad recess area PR3a and PR3b. The at least one upper pad recess area PR3a and PR3b may be disposed in the connection area CA.

In the first upper stack structure GS3a, the at least one upper pad recess area PR3a and PR3b may have an open upper portion. The at least one upper pad recess area PR3a and PR3b may include a first upper pad recess area PR3a, and a second upper pad recess area PR3b that is farther away from the memory cell array area MA than the first upper pad recess area PR3a.

The first upper pad recess area PR3a may include a first upper gate pad area GP3a and a first dummy sidewall PR_Sd3a. The second upper pad recess area PR3b may include a second upper gate pad area GP3b and second dummy sidewalls PR_Sd3b, PR_Sd3c, and PR_Sd3d.

The first upper gate pad area GP3a may have a shape of stairs that go down by steps at substantially the same slope as the first intermediate gate pad area GP2a.

The first dummy sidewall PR_Sd3a of the first upper pad recess area PR3a may have a shape of stairs that go down by steps at substantially the same slope as the first dummy sidewall PR_Sd2a of the first intermediate pad recess area PR2a. The first dummy sidewall PR_Sd3a may have a steeper slope than the first upper gate pad area GP3a. The first dummy sidewall PR_Sd3a and the first upper gate pad area GP3a may face each other and may be disposed at substantially the same height level. A distance between the first dummy sidewall PR_Sd3a and the first upper gate pad area GP3a may become narrower from top to bottom.

The second upper gate pad area GP3b may have substantially the same shape of stairs as the first upper gate pad area GP3a.

The second dummy sidewalls PR_Sd3b, PR_Sd3c, and PR_Sd3d of the second upper pad recess area PR3b may include a first dummy portion PR_Sd3b, a second dummy portion PR_Sd3c, and a third dummy portion PR_Sd3d.

The first dummy portion PR_Sd3b may have substantially the same shape as the first dummy sidewall PR_Sd3a. For example, the first dummy portion PR_Sd3b may have a shape of stairs that go down by steps at the second average slope in the direction toward the memory cell array area MA. The first dummy portion PR_Sd3b may have a steeper slope than the second upper gate pad area GP3b. The first dummy portion PR_Sd3b and the second upper gate pad area GP3b may face each other and may be disposed at substantially the same height level. A distance between the first dummy portion PR_Sd3b and the second upper gate pad area GP3b may become narrower from top to bottom.

The second dummy portion PR_Sd3c may be adjacent to the first dummy portion PR_Sd3b and may be disposed at a higher level than the first dummy portion PR_Sd3b, and may have a steeper slope than the slope of the first dummy portion PR_Sd3b. The second dummy portion PR_Sd3c may be formed in the vertical direction Z. For example, the slope of the second dummy portion PR_Sd3c may extend in the vertical direction Z.

The third dummy portion PR_Sd3d may be adjacent to the second upper gate pad area GP3b and may be disposed at a higher level than the second upper gate pad area GP3b. The third dummy portion PR_Sd3d may face the second dummy portion PR_Sd3c. The third dummy portion PR_Sd3d may have a steeper slope than the slope of the first dummy portion PR Sd3b. The third dummy portion PR_Sd3d may be formed and disposed in the vertical direction Z. For example, the slope of the third dummy portion PR_Sd3d may extend in the vertical direction Z.

A distance between the second dummy portion PR_Sd3c and the third dummy portion PR_Sd3d may become narrower from top to bottom. The minimum distance between the second dummy portion PR_Sd3c and the third dummy portion PR_Sd3d may be equal to or greater than the maximum distance between the first dummy portion PR_Sd3b and the second upper gate pad area GP3b. The second dummy portion PR_Sd3c and the third dummy portion PR_Sd3d may be disposed at a level substantially the same as the first dummy sidewall PR Sd3a and the first upper gate pad area GP3a. The present disclosure is not limited thereto. In an embodiment, a distance between the second dummy portion PR_Sd3c and the third dummy portion PR_Sd3d may be constant and may be the same as the maximum distance between the first dummy portion PR_Sd3b and the second upper gate pad area GP3b.

At least one of the first upper gate pad area GP3a and the second upper gate pad area GP3b may be formed in substantially the same shape as any one of the first lower gate pad area GP1a, the second lower gate pad area GP1b, the first intermediate gate pad area GP2a, and the second intermediate gate pad area GP2b. For example, at least one of the first upper gate pad area GP3a and the second upper gate pad area GP3b may include a third upper pad (not illustrated), third stepped pad groups (not illustrated) at a lower level than the third upper pad, and one or more third intermediate pads (not illustrated) disposed between the third stepped pad groups.

The second upper stack structure GS3b may expose the at least one upper pad recess area PR3a and PR3b. The upper stack structure GS3b may further include a third upper pad recess area PR3c. The third upper pad recess area PR3c may include a gate pad area GP_U having a shape of stairs that go down by steps in a direction away from the memory cell array area MA, and a dummy pad area GP_D having a shape of stairs that go down by steps in a direction closer to the memory cell array area MA.

The upper structure ST3 may further include at least one upper pad capping pattern PC3a and PC3b on the at least one upper pad recess area PR3a and PR3b. The at least one upper pad capping pattern PC3a and PC3b may fill the at least one upper pad recess area PR3a and PR3b. The at least one upper pad capping pattern PC3a and PC3b may be formed of the same insulating material as each other. For example, the at least one upper pad capping pattern PC3a and PC3b may include an insulating material such as silicon oxide. In an embodiment, the at least one upper pad capping pattern PC3a and PC3b may be consisted of the same insulating material such as silicon oxide. The at least one upper pad capping pattern PC3a and PC3b may include a first upper pad capping pattern PC3a formed on the first upper pad recess area PR3a to fill the first upper pad recess area PR3a, and a second upper pad capping pattern PC3b formed on the second upper pad recess area PR3b to fill the second upper pad recess area PR3b. The maximum thickness of the second upper pad capping pattern PC3b in the vertical direction Z may be greater than the maximum thickness of the first upper pad capping pattern PC3a in the vertical direction Z.

The upper structure ST3 may further include a third upper pad capping pattern PC3c formed on the third upper pad recess area PR3c to fill the third upper pad recess area PR3c.

The first intermediate buffer recess area BR2a and the first intermediate buffer capping pattern BC2a may vertically overlap the second upper pad recess area PR3b and the second upper pad capping pattern PC3b.

The gate pads of the third gate layers GL3 of the upper stack structure GS3 may form the first and second upper gate pad areas GP3a and GP3b, and the gate pads of the third gate layers GL3 of the second upper stack structure GS3 may form the third upper gate pad area GP_U.

Particularly, in describing the third gate layers GL3, the third gate layers of the first upper stack structure GS3a may be referred to as the first upper gate layers GL3_L, and the third gate layers of the second upper stack structure GS3b may be referred to as second and third upper gate layers GL3_Ua and GL3_Ub.

In describing the second and third upper gate layers GL3_Ua and GL3_Ub, the second upper gate layers GL3_Ua may extend from the memory cell array area MA into the connection area CA, and the third upper gate layers GL3_Ub may be spaced apart from the second upper gate layers GL3_Ua and disposed in the connection area CA. The third upper gate layers GL3_Ub may be referred to as dummy upper gate layers that are electrically isolated.

In the first structure ST1, the first lower pad capping pattern PC1a, the first lower buffer capping pattern BC1a, and the second lower pad capping pattern PC1b may be sequentially arranged and spaced apart from each other in a direction away from the memory cell array area MA, that is, in the first horizontal direction X. Each of the first lower pad capping pattern PC1a, the first lower buffer capping pattern BC1a, and the second lower pad capping pattern PC1b may have a shape extending downward from the upper surface of the lower stack structure GS1. The first lower buffer capping pattern BC1a may be disposed at a level higher than or substantially the same as the lower end of the first lower pad capping pattern PC1a. Some of the first gate layers GL1 may be disposed between the first lower pad capping pattern PC1a and the first lower buffer capping pattern BC1a.

In the second structure ST2, the first intermediate pad capping pattern PC2a, the first intermediate buffer capping pattern BC2a, and the second intermediate pad capping pattern PC2b may be sequentially arranged in the first horizontal direction X and spaced apart from each other. Each of the first intermediate pad capping pattern PC2a, the first intermediate buffer capping pattern BC2a, and the second intermediate pad capping pattern PC2b may have a shape extending downward from the upper surface of the intermediate stack structure GS2. The first intermediate buffer capping pattern BC2a may be disposed at a level higher than or substantially the same as the lower end of the first intermediate pad capping pattern PC2a. Some of the second gate layers GL2 may be disposed between the first intermediate pad capping pattern PC2a and the first intermediate buffer capping pattern BC2a.

In the third structure ST3, the third upper pad capping pattern PC3c, the first upper pad capping pattern PC3a, and the second upper pad capping pattern PC3b may be sequentially arranged in the first horizontal direction X. Some of the first upper gate layers GL3_L may be disposed between the first upper pad capping pattern PC3a and the second upper pad capping pattern PC3b.

The connection area CA may include first to sixth regions disposed in a direction away from the memory cell array area MA. The first upper pad capping pattern PC3a, the first intermediate pad capping pattern PC2a, and the first lower pad capping pattern PC1a may be disposed in different regions of the first, second, and third regions. For example, the first upper pad capping pattern PC3a, the first intermediate pad capping pattern PC2a, and the first lower pad capping pattern PC1a may be disposed in the third region, the second region, and the first region or in the first region, the second region, and the third region, respectively. The second intermediate buffer capping pattern BC2a and the second upper pad capping pattern PC3b may be disposed in the fourth region. The first lower buffer capping pattern BC1a and the second intermediate pad capping pattern PC2b may be disposed in the fifth region. The second lower pad capping pattern PC1b may be disposed in the sixth region. The first to sixth regions may have widths substantially the same as or similar to each other.

There may be no separate buffer area (or forced fence area) between the first to sixth regions. In other words, an end on the right side of the capping pattern disposed in (n) th region and an end on the left side of the capping pattern disposed in (n+1)th region may substantially coincide or correspond to each other. In an embodiment, when viewed in a cross-sectional view, no overlapping may exist between two adjacent regions in the vertical direction Z. In other words, when viewed in a plan view, the two adjacent regions may abut each other (i.e., may touch each other).

In each of the plurality of structures ST, interlayer insulating layers and gate layers, which are alternately stacked on each other, may be disposed between patterns spaced apart from each other. For example, in the first structure ST1, the first lower pad capping pattern PC1a and the first lower buffer capping pattern BC1a may be spaced apart from each other by the first lower gate layers GL1 and the lower interlayer insulating layers ILD1, which are alternately stacked on each other. In other words, the first lower gate layers GL1 and the lower interlayer insulating layers ILD1 may be disposed between the first lower pad capping pattern PC1a and the first lower buffer capping pattern BC1a. On the other hand, the first lower buffer capping pattern BC1a and the second lower pad capping pattern PC1b may be formed integrally. For example, the first lower buffer capping pattern BC1a and the second lower pad capping pattern PC1b may be connected without boundary therebetween.

Likewise, in the second structure ST2, the first intermediate pad capping pattern PC2a and the first intermediate buffer capping pattern BC2a may be spaced apart from each other by the second interlayer insulating layers ILD2 and the second gate layers GL2, which are alternately stacked on each other, and the first intermediate buffer capping pattern BC2a and the second intermediate pad capping pattern PC2b may be formed integrally. For example, the first intermediate buffer capping pattern BC2a and the second intermediate pad capping pattern PC2b may be connected without boundary therebetween.

In the third structure ST3, the upper pad capping patterns PC3a and PC3b may be spaced apart from each other by the third interlayer insulating layers ILD3 and the third gate layers GL3, which are alternately stacked on each other.

The first to third gate layers GL1, GL2, and GL3 may include lower gate layers, intermediate gate layers on the lower gate layers, and upper gate layers on the intermediate gate layers. The lower gate layers may include a lower select gate electrode and a lower erase control gate electrode. The intermediate gate layers may include word lines. The upper gate layers may include an upper select gate electrode and an upper erase control gate electrode.

The first gate layers GL1 may form the lower gate layers and some of the intermediate gate layers. The second gate layers GL2 may form some of the intermediate gate layers. The first upper gate layers GL3_L of the third gate layers GL3 may form some of the intermediate gate layers, and the second upper gate layers GL3_Ua of the third gate layers GL3 may form the upper gate layers. Accordingly, the first gate layers GL1 may include some of the word lines together with the lower select gate electrode and the lower erase control gate electrode, the second gate layers GL2 may include some of the word lines, the first upper gate layers GL3_L may include some of the word lines, and the second upper gate layers GL3_Ua may include the upper select gate electrode and the upper erase control gate electrode. The word lines may be formed in the first gate layers GL1, the second gate layers GL2, and the third gate layers GL3.

The semiconductor device 1 may further include vertical memory structures VC penetrating the stack structures GS1, GS2, and GS3 in the memory cell array area MA. The vertical memory structures VC that penetrate the stack structures GS1, GS2, and GS3 may be electrically connected to the source structure SS. The vertical memory structures VC may also be referred to as vertical channel structures.

The semiconductor device 1 may further include contact plugs penetrating at least the structures ST. The contact plugs may be disposed in the connection area CA. The contact plugs may penetrate the structures ST and the source structure SS and extend into the peripheral circuit structure PERI. In an embodiment, the contact plugs may extend lengthwise in the vertical direction Z.

The contact plugs may include first gate contact plugs GC and first peripheral contact plugs PCa.

The contact plugs may further include second gate contact plugs GCa.

The lower stack structure GS1 may further include first isolation insulating layers SP1, the intermediate stack structure GS2 may further include second isolation insulating layers SP2, and the upper stack structure GS3 may further include third isolation insulating layers SP3.

The first isolation insulating layers SP1 may be disposed between the first gate contact plugs GC and the first gate layers GL1 of the first gate layers GL1, which are not electrically connected to the first gate contact plugs GC. The second isolation insulating layers SP2 may be disposed between the first gate contact plugs GC and the second gate contact plugs GL2 of the second gate layers GL2, which are not electrically connected to the first gate contact plugs GC. The third isolation insulating layers SP3 may be disposed between the first gate contact plugs GC and the third gate contact plugs GL3 of the third gate layers GL3, which are not electrically connected to the first gate contact plugs GC. The first to third isolation insulating layers SP1, SP2, and SP3 may be formed of an insulating material such as silicon oxide.

The first gate contact plugs GC may be electrically connected to the gate pads of the gate layers GL1, GL2, and GL3_L of the lower stack structure GS1, the intermediate stack structure GS2, and the first upper stack structure GS3a. The first gate contact plugs GC may contact the gate pads GP of the gate layers GL1, GL2, and GL3_L of the lower stack structure GS1, the intermediate stack structure GS2, and the first upper stack structure GS3a while penetrating the gate pads GP of the gate layers GL1, GL2, and GL3_L of the lower stack structure GS1, the intermediate stack structure GS2, and the first upper stack structure GS3a.

The first gate contact plugs GC may include a horizontal extension PE contacting each of the gate pads GP of the gate layers GL1, GL2, and GL3_L of the lower stack structure GS1, the intermediate stack structure GS2, and the first upper stack structure GS3a. The horizontal extension PE of one of the first gate contact plugs GCs may be in contact with one of the gate pads GPs. The horizontal extension PE may have a shape such that it contacts the gate pad GP while penetrating the same. For example, a side surface of the horizontal extension PE may be in contact with the gate pad GP. In one first gate contact plug GC, the horizontal extension PE may be a part extending or protruding from the center of the first gate contact plug GC in the direction toward the gate pad GP. For example, the horizontal extension PE may extend in the first horizontal direction X from the center of the first gate contact plug GC.

The second gate contact plugs GCa may be electrically connected to the gate pads of the second upper gate layers GL3_Ua of the second upper stack structure GS3b. The second gate contact plugs GCa may be formed on the gate pads of the second upper gate layers GL3_Ua of the second upper stack structure GS3b, while contacting the gate pads of the second upper gate layers GL3_Ua of the second upper stack structure GS3b.

The first gate contact plugs GC may be disposed at substantially the same height as each other. For example, the first gate contact plugs GC may have upper ends positioned at substantially the same level as each other and lower ends positioned at substantially the same level as each other.

The first gate contact plugs GC may include first upper gate contact plugs GC3a, first intermediate gate contact plugs GC2a, first lower gate contact plugs GC1a, second upper gate contact plugs GC3b, second intermediate gate contact plugs GC2b, and second lower gate contact plugs GC1b, which may be sequentially arranged in the first direction X away from the memory cell array area MA.

The first lower gate contact plugs GC1a may penetrate the lower stack structure GS1, the first lower pad capping pattern PC1a, the intermediate stack structure GS2, and the upper stack structure GS3, may be electrically connected to the gate pads of the first lower gate pad area GP1a of the first lower pad recess area PR1a of the lower stack structure GS1, and may be electrically insulated, i.e. spaced apart from the remaining gate layers by the first to third isolation insulating layers SP1, SP2, and SP3.

The second lower gate contact plugs GC1b may penetrate the lower stack structure GS1, the second lower pad capping pattern PC1b, the intermediate stack structure GS2, and the upper stack structure GS3, may be electrically connected to the gate pads of the second lower gate pad area GP1b of the second lower pad recess area PR1b of the lower stack structure GS1, and may be electrically insulated, i.e. spaced apart from the remaining gate layers by the first to third isolation insulating layers SP1, SP2, and SP3.

The first and second lower gate contact plugs GC1a and GC1b may be electrically connected to the lower gate layers GL1 through the gate pads of the first and second lower gate pad areas GP1a and GP1b, and may be electrically insulated from the intermediate and upper gate layers GL2 and GL3.

The first intermediate gate contact plugs GC2a may penetrate the lower stack structure GS1, the intermediate stack structure GS2, the first intermediate pad capping pattern PC2a and the upper stack structure GS3, may be electrically connected to the gate pads GP of the first intermediate gate pad area GP2a of the first intermediate pad recess area PR2a of the intermediate stack structure GS2, and may be electrically insulated, i.e. spaced apart from the remaining gate layers by the first to third isolation insulating layers SP1, SP2, and SP3.

The second intermediate gate contact plugs GC2b may penetrate the lower stack structure GS1, the first lower buffer capping pattern BC1a, the intermediate stack structure GS2, the second intermediate pad capping pattern PC2b, and the upper stack structure GS3, may be electrically connected to the gate pads of the second intermediate gate pad area GP2b of the second intermediate pad recess area PR2b of the intermediate stack structure GS2, and may be electrically insulated, i.e. spaced apart from the remaining gate layers by the first to third isolation insulating layers SP1, SP2, and SP3.

The first and second intermediate gate contact plugs GC2a and GC2b may be electrically connected to the intermediate gate layers GL2 through the gate pads of the first and second intermediate gate pad areas GP2a and GP2b, and may be electrically insulated from the lower and upper gate layers GL1 and GL3.

The first upper gate contact plugs GC3a may penetrate the lower stack structure GS1, the intermediate stack structure GS2, the upper stack structure GS3, and the first upper pad capping pattern PC3a, may be electrically connected to the gate pads of the first upper gate pad area GP3a of the first upper pad recess area PR3a of the first upper stack structure GS3a, and may be electrically insulated, i.e. spaced apart from the remaining gate layers by the first to third isolation insulating layers SP1, SP2, and SP3.

The second upper gate contact plugs GC3b may penetrate the lower stack structure GS1, the intermediate stack structure GS2, the first intermediate buffer capping pattern BC2a, the upper stack structure GS3, and the second upper pad capping pattern PC3b, may be electrically connected to gate pads of the second upper gate pad area GP3b of the second upper pad recess area PR3b of the first upper stack structure GS3a, and may be electrically insulated, i.e. spaced apart from the remaining gate layers by the first to third isolation insulating layers SP1, SP2, and SP3. The first and second upper gate contact plugs GC3a and GC3b may be electrically connected to the first upper gate layers GL3_L through the gate pads of the first and second upper gate pad areas GP3a and GP3b, and may be electrically insulated from the lower and intermediate gate layers GL1 and GL2 and the second and third upper gate layers GL3_Ua and GL3_Ub.

Each of the first gate contact plugs GC may be integrally formed with each other. For example, each of the first gate contact plugs GC may include at least one material layer extending from a lower area to an upper area.

Each of the first gate contact plugs GC may include a lower plug portion P_1, an intermediate plug portion P_2 on the lower plug portion P_1, an upper plug portion P_3 on the intermediate plug portion P_2, a lower junction area BP_L between the lower plug portion P_1 and the intermediate plug portion P_2, and an upper junction area BP_U between the intermediate plug portion P_2 and the upper plug portion P_3.

In each of the first gate contact plugs GC, the width of the upper area of the lower plug portion P_1 and the width of the lower area of the intermediate plug portion P_2 may be different from each other, and the width of the upper area of the intermediate plug portion P_2 and the width of the lower area of the upper plug portion P_3 may be different from each other. Because the width of the upper area of the lower plug portion P_1 and the width of the lower area of the intermediate plug portion P_2 are different from each other in each of the first gate contact plugs GC, there may be a lower bending portion formed in the lower junction area BP_L, and an upper bending portion formed in the upper junction area BP_U. The lower junction area BP_L may be referred to as the lower bending portion of a side surface of each of the first gate contact plugs GC, and the upper junction area BP_U may be referred to as the upper bending portion of a side surface of each of the first gate contact plugs GC. The side surface of each of the first gate contact plugs GC may be described as including the lower bending portion BP_L and the upper bending portion BP_U.

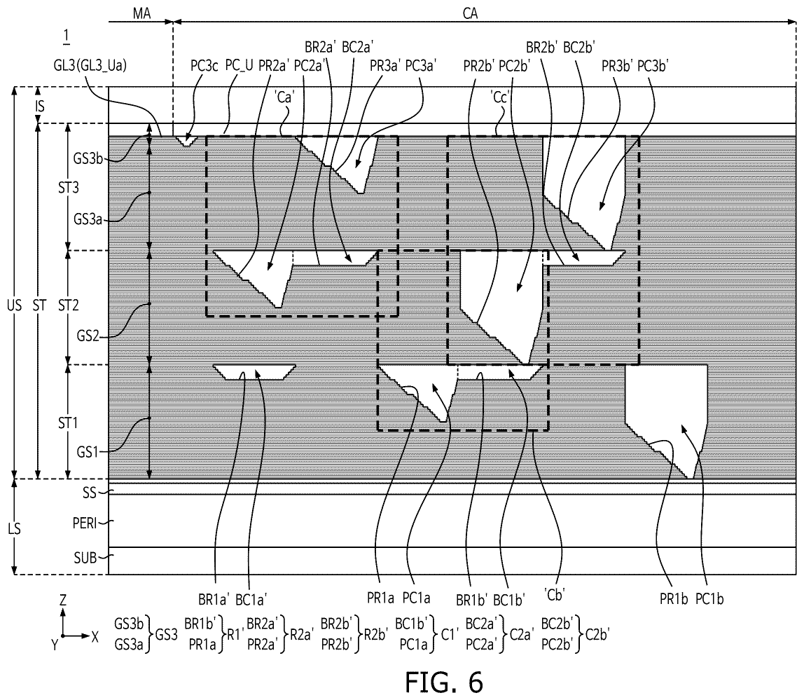

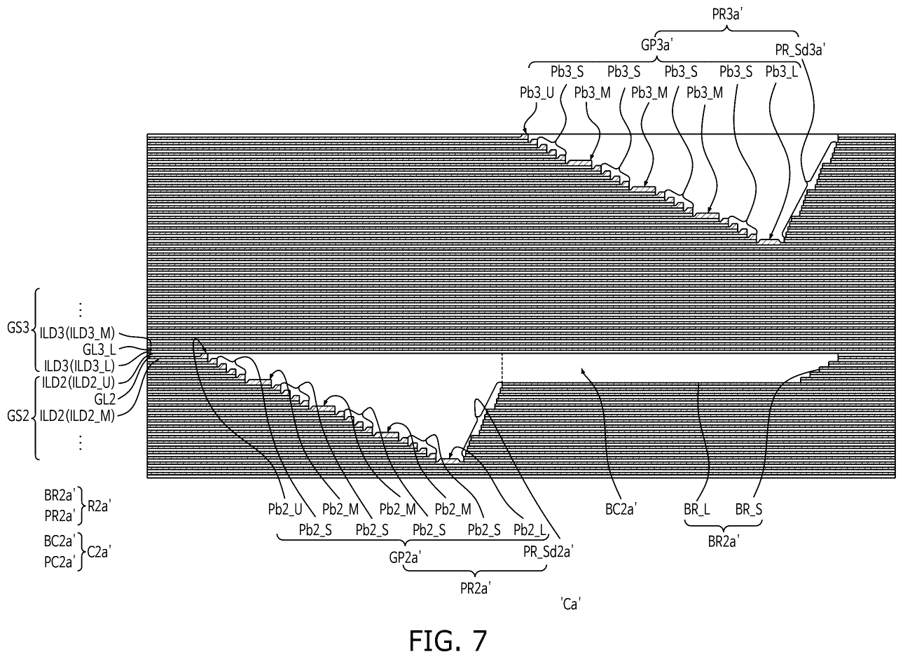

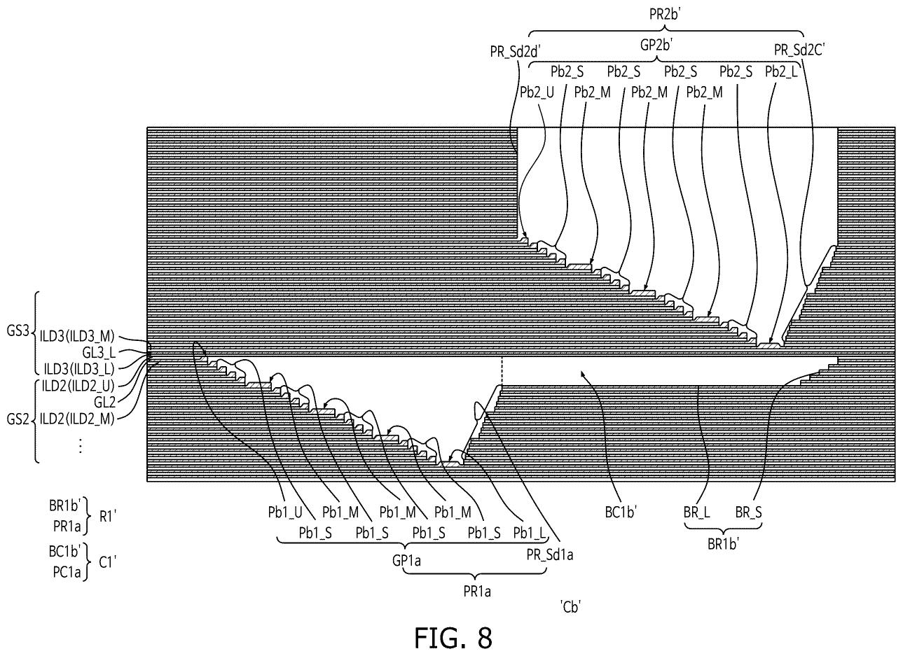

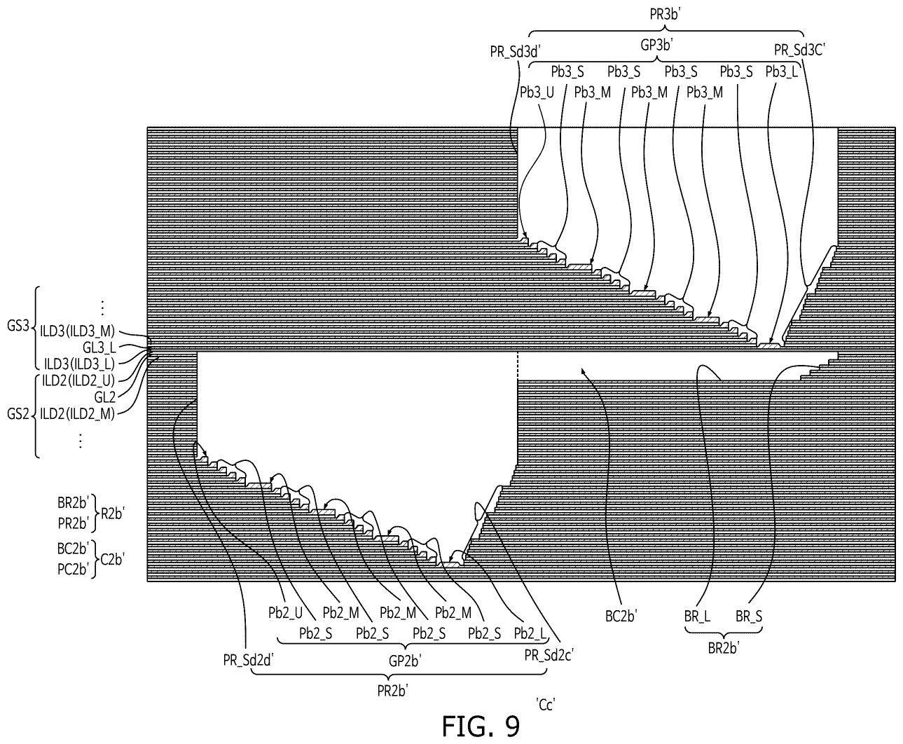

A modification of the upper structure US described above will be described with reference to FIGS. 6 to 9. FIG. 6 is a cross-sectional view conceptually illustrating an area taken along line I-I′ of FIG. 1. FIG. 7 is a partial enlarged view of an area denoted by ‘Ca’ in FIG. 6, FIG. 8 is a partial enlarged view of an area denoted by ‘Cb’ in FIG. 6, and FIG. 9 is a partial enlarged view of an area denoted by ‘Cc’ in FIG. 6.

Referring to the modification shown in FIG. 6, the first intermediate pad capping pattern PC2a, the second intermediate pad capping pattern PC2b, the first upper pad capping pattern PC3a, and the second upper pad capping pattern PC3b illustrated and described with reference to FIG. 2 may be modified into a first intermediate pad capping pattern PC2a′, a second intermediate pad capping pattern PC2b′, a first upper pad capping pattern PC3a′, and a second upper pad capping pattern PC3b′ as illustrated in FIG. 6. The first intermediate pad capping pattern PC2a′, the second intermediate pad capping pattern PC2b′, the first upper pad capping pattern PC3a′, and the second upper pad capping pattern PC3b′ in FIG. 6 may have substantially the same shape and structure as the examples of the first intermediate pad capping pattern PC2a, the second intermediate pad capping pattern PC2b, the first upper pad capping pattern PC3a, and the second upper pad capping pattern PC3b illustrated and described with reference to FIG. 2, respectively.

In addition, with respect to the first intermediate pad capping pattern PC2a′, the second intermediate pad capping pattern PC2b′, the first upper pad capping pattern PC3a′, and the second upper pad capping pattern PC3b′ of FIG. 6, a first lower buffer capping pattern BC1a′, a second lower buffer capping pattern BC1b′, a first intermediate buffer capping pattern BC2a′, and a second intermediate buffer capping pattern BC2b′ may be formed. The first lower buffer capping pattern BC1a′ and the first intermediate buffer capping pattern BC2a′ may be omitted. That is, the buffer capping pattern corresponding to the pad recess area having no dummy sidewall formed in the vertical direction Z may be omitted.

In FIG. 6, a lower recess area R1′ may include a second lower buffer recess area BR1b′ and the first lower pad recess area PR1a, a first intermediate recess area R2a′ may include a first intermediate buffer recess area BR2a′ and a first intermediate pad recess area PR2a′, and a second intermediate recess area R2b′ may include a second intermediate buffer recess area BR2b′ and a second intermediate pad recess area PR2b′. Likewise, a lower capping pattern C1′ may include the second lower buffer capping pattern BC1b′ and the first lower pad capping pattern PC1a, a first intermediate capping pattern C2a′ may include the first intermediate buffer capping pattern BC2a′ and the first intermediate pad capping pattern PC2a′, and a second intermediate capping pattern C2b′ may include the second intermediate buffer capping pattern BC2b′ and the second intermediate pad capping pattern PC2b′.

The second lower buffer capping pattern BC1b′ may be integrally formed with the first lower pad capping pattern PC1a, the first intermediate buffer capping pattern BC2a′ may be integrally formed with the first intermediate pad capping pattern PC2a′, and the second intermediate buffer capping pattern BC2b′ may be integrally formed with the second intermediate pad capping pattern PC2b′. As illustrated, a planar area of each of the second lower buffer capping pattern BC1b′, the first intermediate buffer capping pattern BC2a′, and the second intermediate buffer capping pattern BC2b′ may be disposed in the first direction X with respect to the gate pad area of each of the first lower pad capping pattern PC1a, the first intermediate pad capping pattern PC2a′, and the second intermediate pad capping pattern PC2b′, and the gate pad area may be disposed at a lower level than the planar area.

The first lower buffer capping pattern BC1a′, the second lower buffer capping pattern BC1b′, the first intermediate buffer capping pattern BC2a′, and the second intermediate buffer capping pattern BC2b′ may vertically overlap the first intermediate pad capping pattern PC2a′, the second intermediate pad capping pattern PC2b′, the first upper pad capping pattern PC3a′, and the second upper pad capping pattern PC3b′, respectively.

A third lower buffer capping pattern (not illustrated) and a fourth lower buffer capping pattern (not illustrated) vertically overlapping each of the first intermediate buffer capping pattern BC2a′ and the second intermediate buffer capping pattern BC2b′ may be additionally formed. The third lower buffer capping pattern may be integrally formed with the first lower buffer capping pattern BC1a′ and/or the first lower pad capping pattern PC1a. The fourth lower buffer capping pattern may be integrally formed with the second lower buffer capping pattern BC1b′ and/or the second lower pad capping pattern PC1b.

As illustrated in FIGS. 6 to 9, the bottom surface BR_L of the buffer recess areas BR1a′, BR1b′, BR2a′, and BR2b′ where the buffer capping patterns BC1a′, BC1b′, BC2a′, and BC2b′ are formed may be disposed at a level between the highest and the next highest second stepped pad groups of the stepped pad groups Pb2_S. The present disclosure is not limited thereto. In an embodiment, the bottom surface BR_L of each of the buffer recess areas BR1a′, BR1b′, BR2a′, and BR2b′ may be disposed at a level substantially the same as or similar to that of the bottom surface of any one of the pad recess areas PR1a, PR1b, PR2a′, and PR2b′.

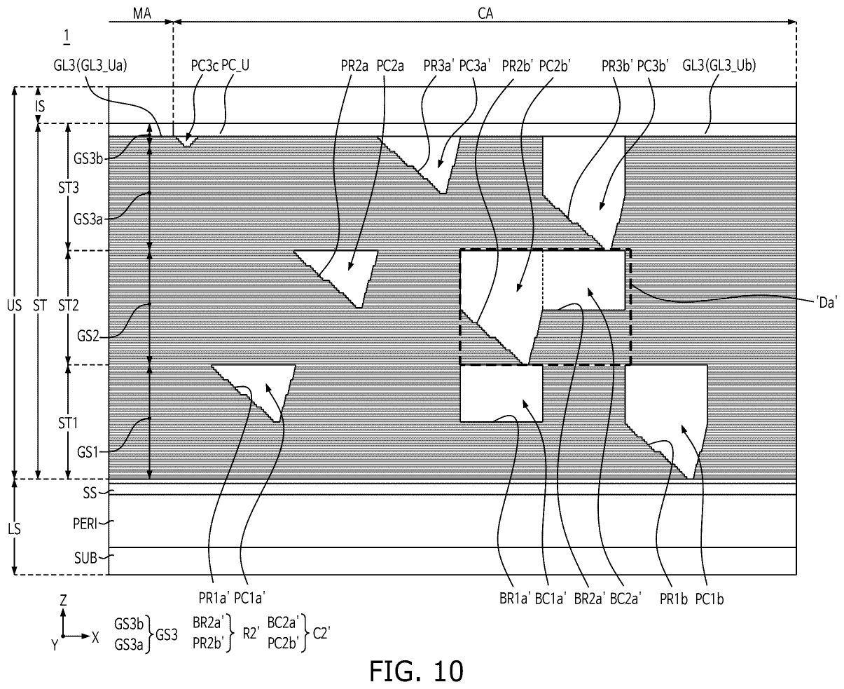

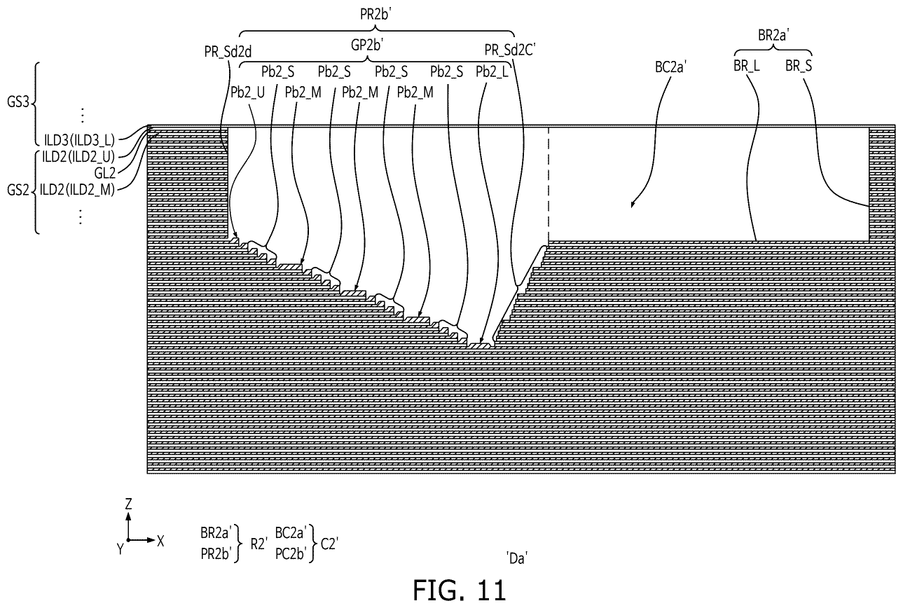

A modification of the upper structure US described above will be described with reference to FIGS. 10 and 11. FIG. 10 is a cross-sectional view conceptually illustrating an area taken along line I-I′ of FIG. 1. FIG. 11 is a partial enlarged view of an area denoted by ‘Da’ in FIG. 10.

Referring to the modification shown in FIG. 10, the first lower pad capping pattern PC1a, the second intermediate pad capping pattern PC2b, the first upper pad capping pattern PC3a, and the second upper pad capping pattern PC3b illustrated and described with reference to FIG. 2 may be modified into a first lower pad capping pattern PC1a′, the second intermediate pad capping pattern PC2b′, the first upper pad capping pattern PC3a′, and a second upper pad capping pattern PC3b′ as illustrated in FIG. 10. The first lower pad capping pattern PC1a′, the second intermediate pad capping pattern PC2b′, the first upper pad capping pattern PC3a′, and the second upper pad capping pattern PC3b′ of FIG. 10 may have substantially the same shape and structure as the examples of the first lower pad capping pattern PC1a, the second intermediate pad capping pattern PC2b, the first upper pad capping pattern PC3a, and the second upper pad capping pattern PC3b illustrated and described with reference to FIG. 2.

In addition, with respect to the second intermediate pad capping pattern PC2b′ and the second upper pad capping pattern PC3b′ of FIG. 10, the first lower buffer capping pattern BC1a′ and a first intermediate buffer capping pattern BC2a′ may be formed. The first lower buffer capping pattern BC1a′ and the first intermediate buffer capping pattern BC2a′ may vertically overlap the second intermediate pad capping pattern PC2b′ and the second upper pad capping pattern PC3b′, respectively.

In FIG. 10, an intermediate recess area R2′ may include the first intermediate buffer recess area BR2a′ and the second intermediate pad recess area PR2b′, and an intermediate capping pattern C2′ may include the first intermediate buffer capping pattern BC2a′ and the second intermediate pad capping pattern PC2b′.

A second lower buffer capping pattern (not illustrated) and a second intermediate buffer capping pattern (not illustrated) vertically overlapping the first intermediate pad capping pattern PC2a′ and the first upper pad capping pattern PC3a′ may be additionally formed. The second lower buffer capping pattern may be integrally formed with the first lower buffer capping pattern BC1a′ and/or the first lower pad capping pattern PC1a′. The second intermediate buffer capping pattern may be integrally formed with the first intermediate pad capping pattern PC2a and/or the second intermediate pad capping pattern PC2b′.

As illustrated in FIGS. 10 and 11, the bottom surface BR_L of the buffer recess areas BR1a′ and BR2a′ where the buffer capping patterns BC1a′ and BC2a′ are formed may be disposed at a level substantially the same as or similar to that of the bottom surface of any one of pad recess areas PR1a′ and PR2a, or disposed at a level substantially the same as or similar to that of a point at which dummy sidewalls PR_Sd2C′ and PR_Sd2d and a second intermediate gate pad area GP2b′ are connected with each other. The present disclosure is not limited thereto. In an embodiment, the bottom surface BR_L of the buffer recess areas BR1a′ and BR2a′ where the buffer capping patterns BC1a′ and BC2a′ are formed may be disposed at any height of the lower structure ST1 or in the intermediate structure ST2 in the Z direction.

As illustrated in FIG. 11, a dummy sidewall PR_Sd2C′, which is an intermediate inclined area that increases in height in the first direction X, may be formed between the flat bottom surface BR_L of the buffer recess area BR2a′ and the gate pad area GP2b′. The pad capping pattern PC2b′ may be disposed on the gate pad area GP2b′ and the dummy sidewall PR_Sd2C′. A first angle formed by the gate pad area GP2b′ and the first direction X may be less than a second angle formed by the dummy sidewall PR_Sd2C′ and the first direction.

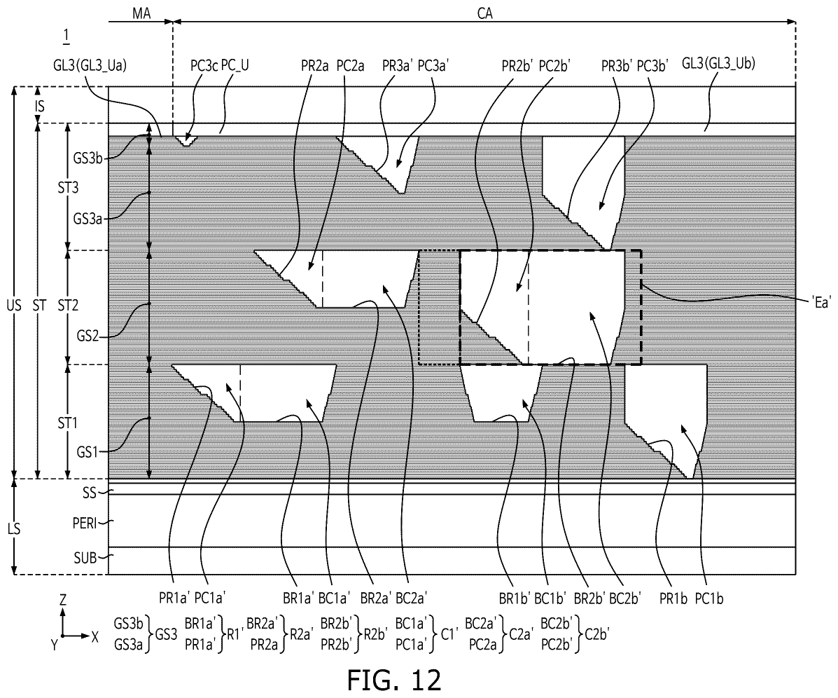

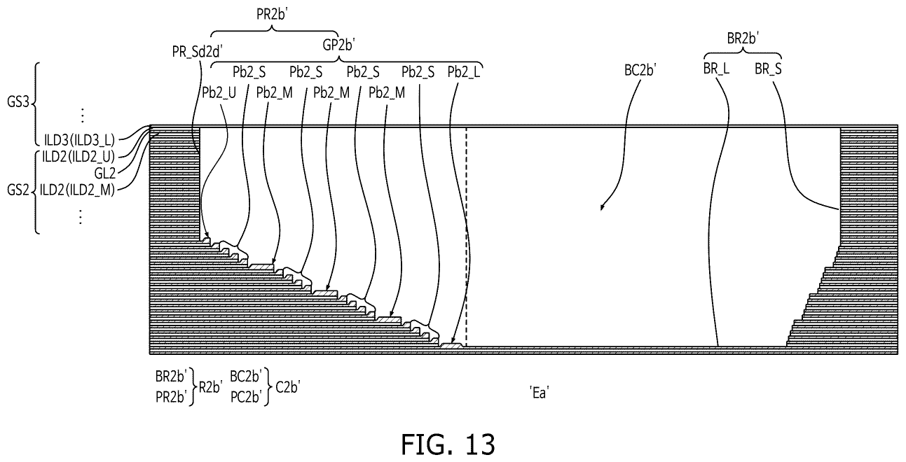

A modification of the upper structure US described above will be described with reference to FIGS. 12 and 13. FIG. 12 is a cross-sectional view conceptually illustrating an area taken along line I-I′ of FIG. 1. FIG. 13 is a partial enlarged view of an area denoted by ‘Ea’ of FIG. 12.

Referring to the modification shown in FIG. 12, the first lower pad capping pattern PC1a, the second intermediate pad capping pattern PC2b, the first upper pad capping pattern PC3a, and the second upper pad capping pattern PC3b illustrated and described with reference to FIG. 2 may be modified into the first lower pad capping pattern PC1a′, the second intermediate pad capping pattern PC2b′, the first upper pad capping pattern PC3a′, and the second upper pad capping pattern PC3b′ as illustrated in FIG. 12. The first lower pad capping pattern PC1a′, the second intermediate pad capping pattern PC2b′, the first upper pad capping pattern PC3a′, and the second upper pad capping pattern PC3b′ of FIG. 12 may have substantially the same shape and structure as the examples of the first lower pad capping pattern PC1a, the second intermediate pad capping pattern PC2b, the first upper pad capping pattern PC3a, and the second upper pad capping pattern PC3b illustrated and described with reference to FIG. 2.

In addition, with respect to the first intermediate pad capping pattern PC2a, the second intermediate pad capping pattern PC2b′, the first upper pad capping pattern PC3a′, and the second upper pad capping pattern PC3b′ of FIG. 12, the first lower buffer capping pattern BC1a′, the second lower buffer capping pattern BC1b′, the first intermediate buffer capping pattern BC2a′, and the second intermediate buffer capping pattern BC2b′ may be formed. The first lower buffer capping pattern BC1a′ and the first intermediate buffer capping pattern BC2a′ may be omitted. That is, the buffer capping pattern corresponding to the pad recess area having no dummy sidewall formed in the vertical direction Z may be omitted.

In FIG. 12, the lower recess area R1′ may include a first lower buffer recess area BR1a′ and a first lower pad recess area PR1a′, the first intermediate recess area R2a′ may include the first intermediate buffer recess area BR2a′ and the first intermediate pad recess area PR2a, and the second intermediate recess area R2b′ may include the second intermediate buffer recess area BR2b′ and the second intermediate pad recess area PR2b′. Likewise, the lower capping pattern C1′ may include the first lower buffer capping pattern BC1a′ and the first lower pad capping pattern PC1a′, the first intermediate capping pattern C2a′ may include the first intermediate buffer capping pattern BC2a′ and the first intermediate pad capping pattern PC2a, and the second intermediate capping pattern C2b′ may include the second intermediate buffer capping pattern BC2b′ and the second intermediate pad capping pattern PC2b′.

The first lower buffer capping pattern BC1a′, the second lower buffer capping pattern BC1b′, the first intermediate buffer capping pattern BC2a′, and the second intermediate buffer capping pattern BC2b′ may vertically overlap the first intermediate pad capping pattern PC2a, the second intermediate pad capping pattern PC2b′, the first upper pad capping pattern PC3a′, and the second upper pad capping pattern PC3b′, respectively.

A third lower buffer capping pattern (not illustrated) that vertically overlaps the first intermediate buffer capping pattern BC2a′ may be additionally formed. The third lower buffer capping pattern may be integrally formed with the first lower buffer capping pattern BC1a′.

As illustrated in FIGS. 12 and 13, the bottom surface BR_L of each of the buffer recess area BR1a′, BR1b′, BR2a′, and BR2b′ where the buffer capping patterns BC1a′, BC1b′, BC2a′, and BC2b′ are formed may be disposed at a level substantially the same as or similar to that of the bottom surface of a corresponding one of the pad recess areas PR1a′, PR2a′, and PR2b′.

Referring to FIG. 13, a planar area of the bottom surface BR_L of the buffer recess area BR2b′ may be disposed along the first direction X with respect to the second intermediate gate pad area GP2b′. A plurality of gate pads of the second intermediate gate pad area GP2b′ may be disposed at a higher level than the bottom surface BR_L of the buffer recess area BR2b′.

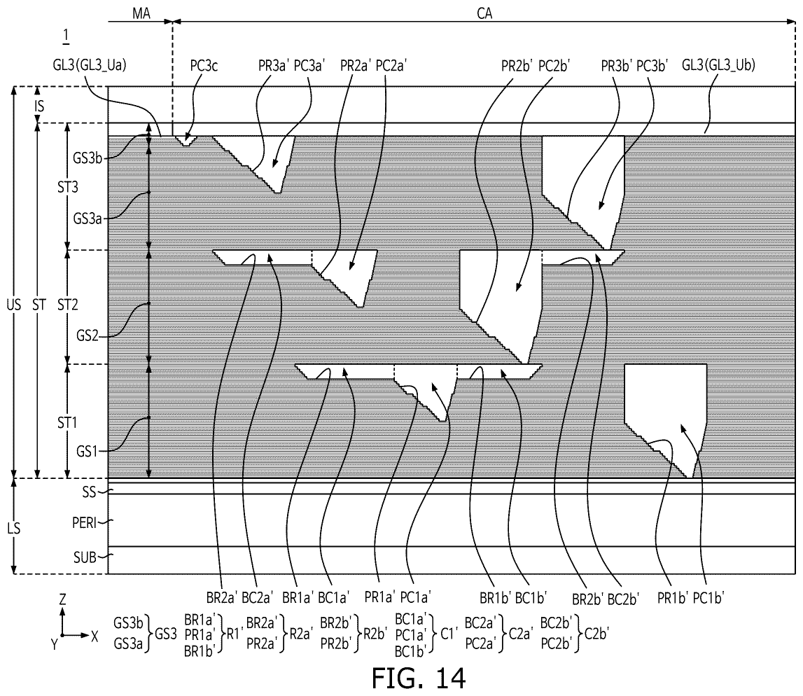

A modification of the upper structure US described above will be described with reference to FIGS. 14 to 17. Each of FIGS. 14 to 17 is a cross-sectional view conceptually illustrating an area taken along line I-I′ of FIG. 1.

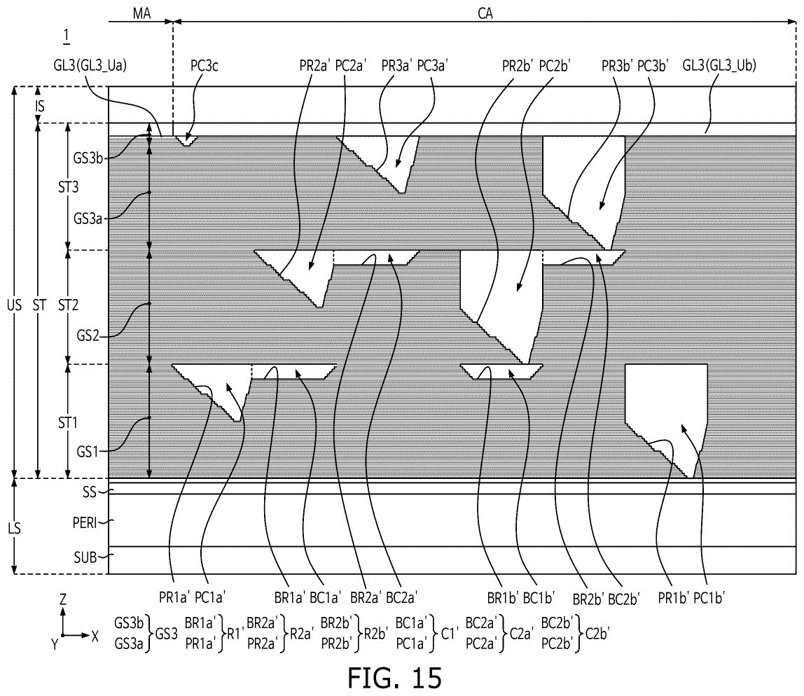

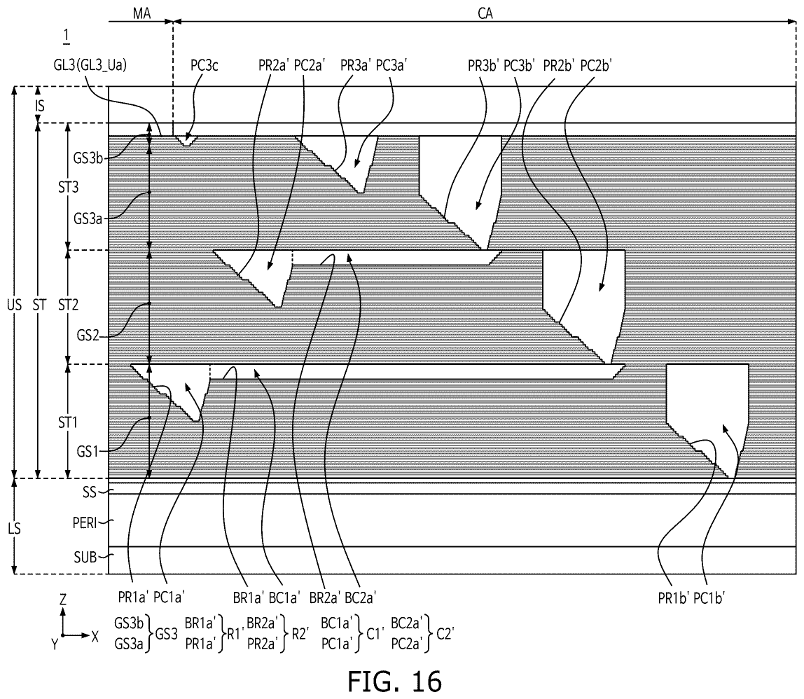

The upper structure US illustrated in each of FIGS. 14 to 16 is a modification from the upper structure US illustrated and described with reference to FIG. 2, which may be formed by modifying at least one of the first lower pad capping pattern PC1a, the first intermediate pad capping pattern PC2a, the second intermediate pad capping pattern PC2b, the first upper pad capping pattern PC3a, and the second upper pad capping pattern PC3b. For example, the upper structure US in FIG. 14 is formed by modifying the positions of the second intermediate pad capping pattern PC2b and the second upper pad capping pattern PC3b of FIG. 2, the upper structure US in FIG. 15 is formed by additionally modifying the positions of the first lower pad capping pattern PC1a and the first upper pad capping pattern PC3a of FIG. 2 from the upper structure US of FIG. 14, and the upper structure US of FIG. 16 is formed by modifying the positions of the first lower pad capping pattern PC1a and the first upper pad capping pattern PC3a of FIG. 2.

In each of FIGS. 14 and 15, the first lower buffer capping pattern BC1a′, the second lower buffer capping pattern BC1b′, the first intermediate buffer capping pattern BC2a′, and the second intermediate buffer capping pattern BC2b′ may vertically overlap the first intermediate pad capping pattern PC2a′, the second intermediate pad capping pattern PC2b′, the first upper pad capping pattern PC3a′, and the second upper pad capping pattern PC3b′, respectively.

In FIG. 16, the first lower buffer capping pattern BC1a′ extends continuously to vertically overlap the first intermediate pad capping pattern PC2a′ and the second intermediate pad capping pattern PC2b′. In addition, the first intermediate buffer capping pattern BC2a′ extends continuously to vertically overlap the first upper pad capping pattern PC3a′ and the second upper pad capping pattern PC3b′.

In each of FIGS. 14 to 17, at least some of the first lower buffer capping pattern BC1a′, the second lower buffer capping pattern BC1b′, the first intermediate buffer capping pattern BC2a′, and the second intermediate buffer capping pattern BC2b′ may be integrally formed with any one of the first lower pad capping pattern PC1a′, the second lower pad capping pattern PC1b′, the first intermediate pad capping pattern PC2a′, and the second intermediate pad capping pattern PC2b′.

Referring to FIG. 14, the first lower buffer recess area BR1a′, the second lower buffer recess area BR1b′, and the first lower pad recess area PR1a′ may be integrated to form the lower recess area R1′, the first intermediate buffer recess area BR2a′ and the first intermediate pad recess area PR2a′ may be integrated to form the first intermediate recess area R2a′, and the second intermediate buffer recess area BR2b′ and the second intermediate pad recess area PR2b′ may be integrated to form the second intermediate recess area R2b′. Additionally, the second lower buffer recess area BR1b′ may be integrally formed with the second lower pad recess area PR1b′. Likewise, the first lower buffer capping pattern BC1a′, the second lower buffer capping pattern BC1b′, and the first lower pad capping pattern PC1a′ may be integrated to form the lower capping pattern C1′, the first intermediate buffer capping pattern BC2a′ and the first intermediate pad capping pattern PC2a′ may be integrated to form the first intermediate capping pattern C2a′, and the second intermediate buffer capping pattern BC2b′ and the second intermediate pad capping pattern PC2b′ may be integrated to form the second intermediate capping pattern C2b′. Additionally, the second lower buffer capping pattern BC1b′ may also be integrally formed with the second lower pad capping pattern PC1b′. For example, the second lower buffer capping pattern BC1b′ may be connected to the second lower pad capping pattern PC1b′.

Referring to FIG. 14, a planar area of the first intermediate buffer capping pattern BC2a′ is disposed close to the memory cell array area MA with respect to a gate pad area of the first intermediate pad capping pattern PC2a′. The gate pad area of the first intermediate pad capping pattern PC2a′ may be positioned at a lower level than the planar area of the first intermediate buffer capping pattern BC2a′. Likewise, the planar area of the first lower buffer capping pattern BC1a′ may be disposed close to the memory cell array area MA with respect to the gate pad area of the first lower pad capping pattern PC1a′, and the gate pad area of the first lower pad capping pattern PC1a′ may be positioned at a lower level than the planar area of the first lower buffer capping pattern BC1a′. Additionally, the planar area of the second lower buffer capping pattern BC1b′ may be positioned at a level substantially the same as the planar area of the first lower buffer capping pattern BC1a′ along the first direction X with respect to the gate pad area of the first lower pad capping pattern PC1a′.

Referring to FIG. 15, the first lower buffer recess area BR1a′ and the first lower pad recess area PR1a′ may be integrated to form the lower recess area R1′, the first intermediate buffer recess area BR2a′ and the first intermediate pad recess area PR2a′ may be integrated to form the first intermediate recess area R2a′, and the second intermediate buffer recess area BR2b′, and the second intermediate pad recess area PR2b′ may be integrated to form the second intermediate recess area R2b′. Additionally, the first lower buffer recess area BR1a′ may also be integrally formed with the second lower buffer recess area BR1b′. Additionally, the first intermediate buffer recess area BR2a′ may also be integrally formed with the second intermediate pad recess area PR2b′. Likewise, the first lower buffer capping pattern BC1a′ and the first lower pad capping pattern PC1a′ may be integrated to form the lower capping pattern C1′, the first intermediate buffer capping pattern BC2a′ and the first intermediate pad capping pattern PC2a′ may be integrated to form the first intermediate capping pattern C2a′, and the second intermediate buffer capping pattern BC2b′ and the second intermediate pad capping pattern PC2b′ may be integrated to form the second intermediate capping pattern C2b′. Additionally, the first lower buffer capping pattern BC1a′ may also be integrally formed with the second lower buffer capping pattern BC1b′. Additionally, the first intermediate buffer capping pattern BC2a′ may also be integrally formed with the second intermediate pad capping pattern PC2b′.

Referring to FIG. 16, the first lower buffer recess area BR1a′ and the first lower pad recess area PR1a′ may be integrated to form the lower recess area R1′, and the first intermediate buffer recess area BR2a′ and the first intermediate pad recess area PR2a′ may be integrated to form the intermediate recess area R2′. Additionally, the first lower buffer recess area BR1a′ may also be integrally formed with the second lower pad recess area PR1b′, and the first intermediate buffer recess area BR2a′ may also be integrally formed with the second intermediate pad recess area PR2b′. Likewise, the first lower buffer capping pattern BC1a′ and the first lower pad capping pattern PC1a′ may be integrated to form the lower capping pattern C1′, and the first intermediate buffer capping pattern BC2a′ and the first intermediate pad capping pattern PC2a′ may be integrated to form the intermediate capping pattern C2′. Additionally, the first lower buffer capping pattern BC1a′ may also be integrally formed with the second lower pad capping pattern PC1b′, and the first intermediate buffer capping pattern BC2a′ may also be integrally formed with the second intermediate pad capping pattern PC2b′.

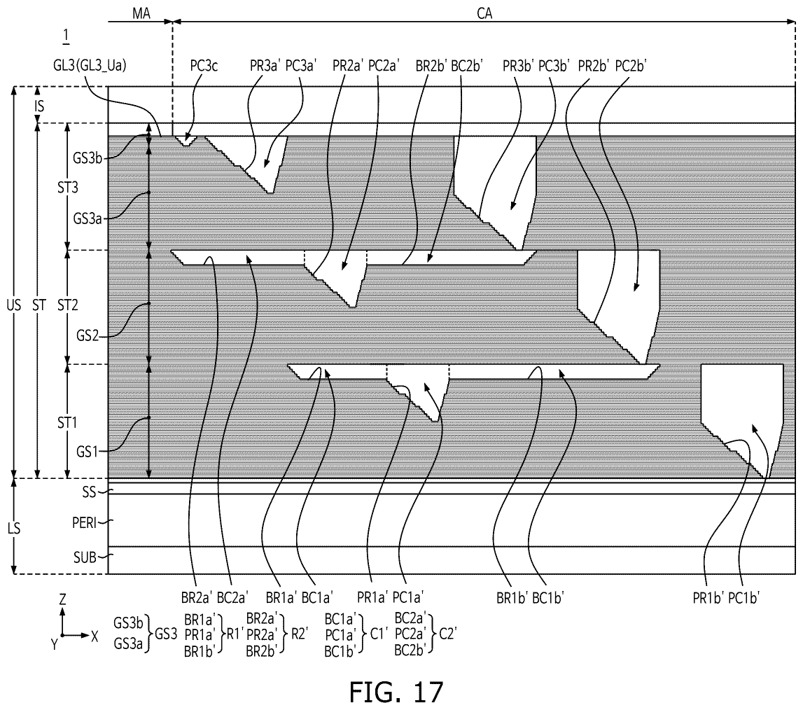

Referring to FIG. 17, the first lower buffer recess area BR1a′, the second lower buffer recess area BR1b′, and the first lower pad recess area PR1a′ may be integrated to form the lower recess area R1′, and the first intermediate buffer recess area BR2a′, the second intermediate buffer recess area BR2b′, and the first intermediate pad recess area PR2a′ may be integrated to form the intermediate recess area R2′. Additionally, the second lower buffer recess area BR1b′ may be integrally formed with the second lower pad recess area PR1b′. Additionally, the second intermediate buffer recess area BR2b′ may also be integrally formed with the second intermediate pad recess area PR2b′. Likewise, the first lower buffer capping pattern BC1a′, the second lower buffer capping pattern BC1b′, and the first lower pad capping pattern PC1a′ may be integrated to form the lower capping pattern C1′, and the first intermediate buffer capping pattern BC2a′, the second intermediate buffer capping pattern BC2b′, and the first intermediate pad capping pattern PC2a′ may be integrated to form the intermediate capping pattern C2′. Additionally, the second lower buffer capping pattern BC1b′ may also be integrally formed with the second lower pad capping pattern PC1b′. For example, the second lower buffer capping pattern BC1b′ may be connected to the second lower pad capping pattern PC1b′. Additionally, the second intermediate buffer capping pattern BC2b′ may also be integrally formed with the second intermediate pad capping pattern PC2b′. For example, the second intermediate buffer capping pattern BC2b′ may be connected to the second intermediate pad capping pattern PC2b′.

The aspects are not limited to the examples of structures illustrated and described with reference to FIGS. 6 to 17. For example, in some aspects of the disclosure, certain structures illustrated in each of FIGS. 6 to 17 may be combined with each other. Each of the structures combining the pad capping pattern and the buffer capping pattern as illustrated and described with reference to FIGS. 6 to 17 may be formed on any one of the plurality of structures ST of the semiconductor device 1, and the pad capping pattern vertically overlapping the buffer capping pattern integrally formed with another pad capping pattern as illustrated and described with reference to FIGS. 6 to 17 may be formed on the structure positioned on top of any of the structures. The width, in the first horizontal direction X of FIGS. 6 to 17, of the pad capping pattern vertically overlapping the buffer capping pattern may be the same as the width, in the first horizontal direction X, of the buffer capping pattern. Additionally, the width, in the first horizontal direction X, of the pad capping pattern integrally formed with the buffer capping pattern may be the same as the width, in the first horizontal direction X, of the integrally formed buffer capping pattern.

The pad capping pattern and the buffer capping pattern formed to be spaced apart from each other on one structure as illustrated and described with reference to FIGS. 6 to 17 may be formed by being combined with each other. The bottom surface BR L of the buffer recess area where the buffer capping pattern is formed as illustrated and described with reference to FIGS. 6 to 17 may be disposed at any height in the Z direction of the lower structure ST1 or in the intermediate structure ST2.

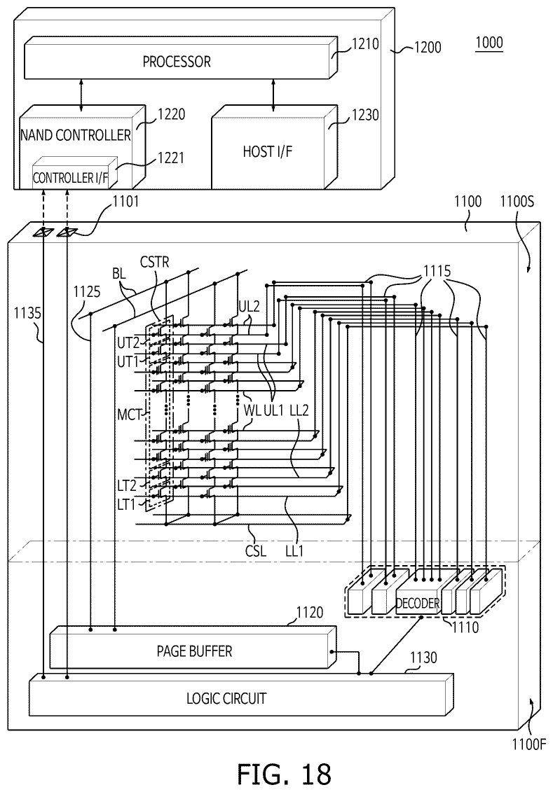

Next, a data storage system including a semiconductor device will be described with reference to FIGS. 18, 19, and 20, respectively.

FIG. 18 is a view schematically illustrating a data storage system including a semiconductor device.

Referring to FIG. 18, a data storage system 1000 may include a semiconductor device 1100 and a controller 1200 electrically connected to the semiconductor device 1100 to control the semiconductor device 1100. The data storage system 1000 may be a storage device including the semiconductor device 1100, or an electronic device including the storage device. For example, the data storage system 1000 may be a solid state drive (SSD) device, a universal serial bus (USB), a computing system, a medical device, or a communication device including the semiconductor device 1100.

The data storage system 1000 may be an electronic system that stores data.

The semiconductor device 1100 may be a non-volatile memory device. For example, the semiconductor device 1100 may be the semiconductor device 1 according to any one of the aspects described above with reference to FIGS. 1 to 17. The semiconductor device 1100 may include a first structure 1100F and a second structure 1100S on the first structure 1100F.

The first structure 110OF may be a peripheral circuit structure including a decoder circuit 1110, a page buffer 1120, and a logic circuit 1130. For example, the first structure 110OF may include the peripheral circuit structure PERI described above. The peripheral circuit element described above may be a transistor that forms the decoder circuit 1110, the page buffer 1120, and the logic circuit 1130.

The second structure 1100S may be a memory structure including a bit line BL, a common source line CSL, word lines WL, first and second gate upper lines UL1 and UL2, first and second gate lower lines LL1 and LL2, and memory cell strings CSTR formed between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified according to embodiments.

The plurality of memory cell transistors MCT may include some of the gate layers described above that may be the word lines, the channel layer, and a data storage structure 50.

In an exemplary embodiment, the upper transistors UT1 and UT2 may include a string select transistor, and the lower transistors LT1 and LT2 may include a ground select transistor. The gate lower lines LL1 and LL2 may each be gate electrodes of the lower transistors LT1 and LT2. The word lines WL may be the gate electrodes of the memory cell transistors MCT, and the gate upper lines UL1 and UL2 may be the gate electrodes of the upper transistors UT1 and UT2, respectively.

The gate layers GL described above may form the gate lower lines LL0 and LL2, the word lines WL, and the gate upper lines UL1 and UL2.

The common source line CSL, the first and second gate lower lines LL0 and LL2, the word lines WL, and the first and second gate upper lines UL0 and UL2 may be electrically connected to the decoder circuit 1110 through first connection lines 1115 extending from the first structure 1100F to the second structure 1100S.

The bit lines BL may be electrically connected to the page buffer 1120 through second connection wires 1125 extending from the first structure 1100F to the second structure 1100S. The bit lines BL may be the bit lines described above.

In the first structure 1100F, the decoder circuit 1110 and the page buffer 1120 may perform a control operation on at least one selected memory cell transistor MCT of the plurality of memory cell transistors MCT. The decoder circuit 1110 and the page buffer 1120 may be controlled by the logic circuit 1130.

The semiconductor device 1100 may further include an input and output pad 1101. The semiconductor device 1100 may communicate with the controller 1200 through the input and output pad 1101 electrically connected to the logic circuit 1130. The input and output pad 1101 may be electrically connected to the logic circuit 1130 through an input and output connection wiring 1135 extending from the first structure 1100F to the second structure 1100S. Accordingly, the controller 1200 may be electrically connected to the semiconductor device 1100 through the input and output pad 1101 and may control the semiconductor device 1100.

The controller 1200 may include a processor 1210, a NAND controller 1220, and a host interface 1230. The data storage system 1000 may include a plurality of semiconductor devices 1100, in which case the controller 1200 may control the plurality of semiconductor devices 1100.

The processor 1210 may control the overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a communication function between the data storage system 1000 and an external host. Upon receiving a control command from the external host through the host interface 1230, the processor 1210 may control the semiconductor device 1100 in response to the control command.

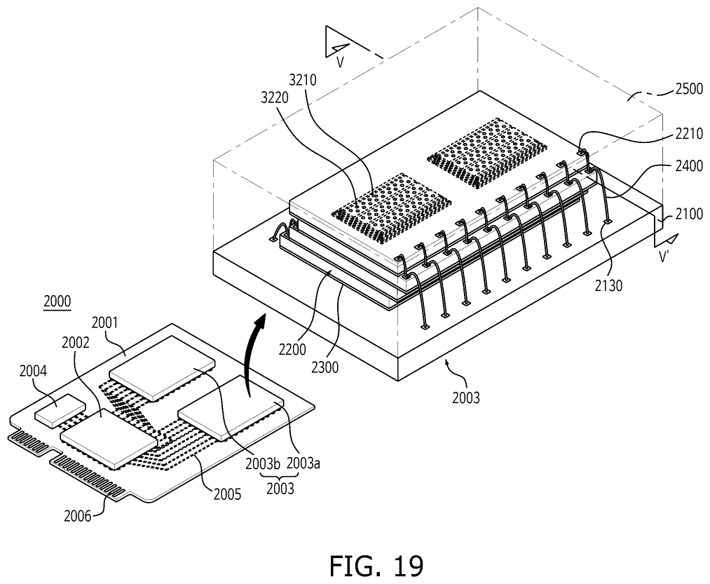

FIG. 19 is a perspective view schematically illustrating an electronic system including a semiconductor device.

Referring to FIG. 19, an electronic system 2000 (e.g., a data storage system) may include a main substrate 2001, a controller 2002 mounted on the main substrate 2001, one or more semiconductor packages 2003, and a DRAM 2004. The semiconductor packages 2003 and the DRAM 2004 may be connected to the controller 2002 by wiring patterns 2005 formed on the main substrate 2001.

The main substrate 2001 may include a connector 2006 including a plurality of pins coupled to an external host. The number and arrangement of the plurality of pins in the connector 2006 may vary according to a communication interface between the electronic system 2000 and the external host. In some examples, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some examples, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor packages 2003.

The controller 2002 may record data in the semiconductor packages 2003 or read data from the semiconductor packages 2003, and may improve the operation speed of the electronic system 2000.

The DRAM 2004 may be a buffer memory provided to alleviate the speed difference between an external host and the semiconductor packages 2003 as the data storage spaces. The DRAM 2004 included in the electronic system 2000 may also operate as a kind of cache memory, and may also provide a space for temporarily storing data in a control operation on the semiconductor packages 2003. If the electronic system 2000 includes the DRAM 2004, the controller 2002 may further include a DRAM controller for controlling the DRAM 2004, in addition to a NAND controller for controlling the semiconductor packages 2003.

The semiconductor packages 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include the semiconductor device according to any one of the aspects described above with reference to FIGS. 1 to 18.

Each of the first and second semiconductor packages 2003a and 2003b may include a package substrate 2100, the semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210.

In some examples, the connection structure 2400 may be a bonding wire electrically connecting the input and output pad 2210 and the package upper pads 2130. Therefore, in each of the first and second semiconductor packages 2003a and 2003b, the semiconductor chips 2200 may be electrically connected to each other using a bonding wire method, and may be electrically connected to the package upper pads 2130 of the package substrate 2100. In some examples, in each of the first and second semiconductor packages 2003a and 2003b, the semiconductor chips 2200 may be electrically connected to each other by a connection structure including through silicon via (TSV), instead of the bonding wire type connection structure 2400.

In some examples, the controller 2002 and the semiconductor chips 2200 may be included in one package. For example, the controller 2002 and the semiconductor chips 2200 may be mounted on a separate interposer substrate different from the main substrate 2001, and the controller 2002 and the semiconductor chips 2200 may be connected to each other by the wiring formed on the interposer substrate.

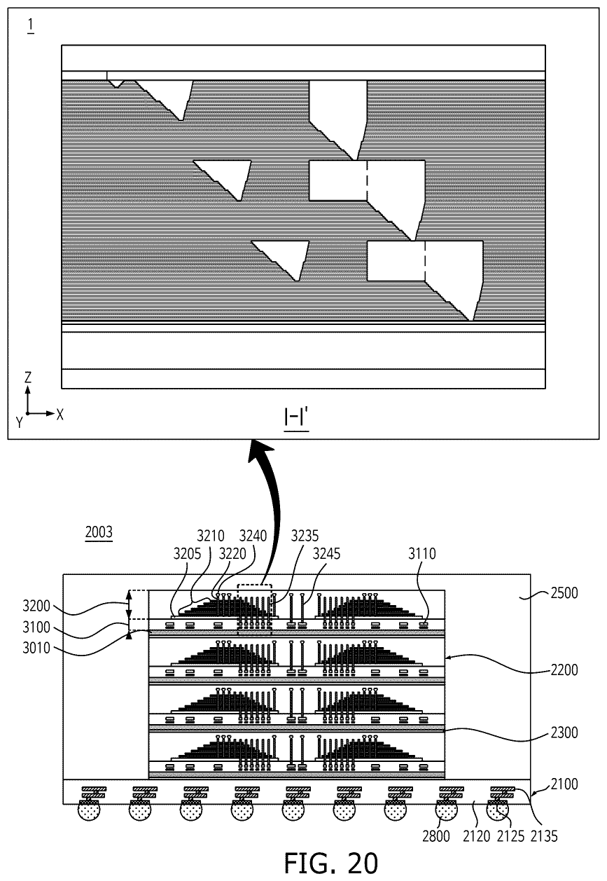

FIG. 20 is a cross-sectional view schematically illustrating a semiconductor package.

FIG. 20 illustrates an exemplary aspect of the semiconductor package 2003 of FIG. 19 and conceptually illustrates an area of the semiconductor package 2003 cut along the cutting line V-V′ in FIG. 19.

Referring to FIGS. 19 and 20, in the semiconductor package 2003, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be connected to the wiring patterns 2005 of a main substrate 2010 of the electronic system 2000 through conductive connection portions 2800.

Each of the semiconductor chips 2200 may include a semiconductor substrate 3010, and a first structure 3100 and a second structure 3200 sequentially stacked on the semiconductor substrate 3010. The first structure 3100 may include a peripheral circuit area including peripheral wirings 3110. The second structure 3200 may include a common source line 3205, a stack structure 3210 on the common source line 3205, memory channel structures 3220 and isolation structures 3230 penetrating the stack structure 3210, bit lines 3240 electrically connected to the memory channel structures 3220, and gate contact plugs electrically connected to word lines WL of the stack structure 3210. The first structure 3100 may include the first structure 1100F of FIG. 18, and the second structure 3200 may include the second structure 1100S of FIG. 18.

Each of the semiconductor chips 2200 may include a through wiring 3245 electrically connected to the peripheral wirings 3110 of the first structure 3100 and extending into the second structure 3200. The through wiring 3245 may penetrate the stack structure 3210 and may be further disposed outside the stack structure 3210.

Each of the semiconductor chips 2200 may further include an input and output connection wiring 3265 electrically connected to the peripheral wirings 3110 of the first structure 3100 and extending into the second structure 3200, and an input and output pad (2210 in FIG. 20) electrically connected to the input and output connection wiring 3265.

In FIG. 20, referring to the partially enlarged illustration of the portion denoted by reference numeral 1, it is noted that the semiconductor chips 2200 of FIGS. 19 and 20 may be modified to include the partially enlarged portion of the structure in cross-section shown in FIG. 2. Accordingly, each of the semiconductor chips 2200 may include the semiconductor device 1 according to any one of the aspects described above with reference to FIGS. 1 to 17.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the aspects described above are illustrative and non-limiting in all respects.

1. A semiconductor device comprising:
a semiconductor substrate comprising a memory cell array area and a connection area, wherein the connection area is adjacent to the memory cell array area in a first horizontal direction parallel to an upper surface of the semiconductor substrate;
a first stack structure disposed on the upper surface of the semiconductor substrate and comprising a plurality of first insulating layers and a plurality of first gate layers, which are alternately stacked on each other in a vertical direction perpendicular to the upper surface of the semiconductor substrate and disposed on the memory cell array area and the connection area, the first stack structure comprising a first recess area disposed on the connection area;
a second stack structure disposed on the first stack structure and comprising a plurality of second insulating layers and a plurality of second gate layers, which are alternately stacked on each other, the second stack structure comprising a second recess area disposed on the connection area;
a first capping pattern disposed on the first recess area;
a second capping pattern disposed on the second recess area, wherein the first recess area comprises a first gate pad area and a first planar area which are connected with each other, the second recess area comprises a second gate pad area, and at least a portion of the second gate pad area overlaps the first planar area in the vertical direction; and
a plurality of gate contact plugs extending lengthwise in the vertical direction and penetrating the first planar area of the first recess area and the second gate pad area.

2. The semiconductor device according to claim 1,
wherein the plurality of first gate layers comprise a plurality of first gate pads covered by the first capping pattern,
the plurality of first gate pads are disposed in the first gate pad area,
the first gate pad area decreases in height relative to the upper surface of the semiconductor substrate in the first horizontal direction away from the memory cell array area, and
the first planar area is connected to the first gate pad area and maintains a height relative to the upper surface of the semiconductor substrate.

3. The semiconductor device according to claim 2,
wherein the first recess area further comprises a first dummy inclined area connecting the first gate pad area to the first planar area and increasing in height relative to the upper surface of the semiconductor substrate in the first horizontal direction away from the memory cell array area, and
the first capping pattern is disposed on the first dummy inclined area.

4. The semiconductor device according to claim 3,
wherein a first angle formed by the first gate pad area and the upper surface of the semiconductor substrate is less than a second angle formed by the first dummy inclined area and the upper surface of the semiconductor substrate.

5. The semiconductor device according to claim 2,
wherein the first planar area is closer to the memory cell array area than the first gate pad area, and
the plurality of first gate pads are disposed at a lower level relative to the upper surface of the semiconductor substrate than the first planar area.

6. The semiconductor device according to claim 2,
wherein the first planar area extends in the first horizontal direction from the first gate pad area, and
the plurality of first gate pads are disposed at a higher level relative to the upper surface of the semiconductor substrate than the first planar area.

7. The semiconductor device according to claim 2,
wherein the plurality of second gate layers comprise a plurality of second gate pads covered by the second capping pattern,
the plurality of second gate pads are disposed in the second gate pad area,
the second gate pad area decreases in height relative to the upper surface of the semiconductor substrate in the first horizontal direction away from the memory cell array area,
the second recess area further comprises a second dummy inclined area connected to the second gate pad area and increasing in height relative to the upper surface of the semiconductor substrate in the first horizontal direction away from the memory cell array area, and
the second capping pattern is disposed on the second gate pad area and the second dummy inclined wall.

8. The semiconductor device according to claim 7,
wherein the second stack structure further comprises:
a first sidewall connected to the second gate pad area; and
a second sidewall connected to the second dummy inclined area wall.

9. The semiconductor device according to claim 1,
wherein the second recess area further comprises a second planar area connected to second gate pad area.

10. The semiconductor device according to claim 1,
wherein the plurality of first gate layers comprise:
a plurality of first upper gate layers; and
a plurality of first lower gate layers comprising a plurality of first gate pads covered by the first capping pattern.

11. The semiconductor device according to claim 1,
wherein the plurality of second gate layers comprise:
a plurality of second upper gate layers; and
a plurality of second lower gate layers comprising a plurality of second gate pads covered by the second capping pattern.

12. The semiconductor device according to claim 1,
wherein the first capping pattern comprises:
a first pad capping pattern disposed on the first gate pad area; and
a first buffer capping pattern disposed on the first planar area,
the second capping pattern comprises a second pad capping pattern disposed on the second gate pad area, and
wherein the second pad capping pattern has a same width as the first buffer capping pattern in the first horizontal direction.

13. The semiconductor device according to claim 1,
wherein the second recess area further comprises a second planar area connected to the second gate pad area,
wherein the first capping pattern comprises:
a first pad capping pattern disposed on the first gate pad area; and
a first buffer capping pattern disposed on the first planar area,
wherein the second capping pattern comprises a second pad capping pattern disposed on the second gate pad area, and
wherein the first pad capping pattern has a same width as the first buffer capping pattern.

14. A semiconductor device comprising:
a semiconductor substrate comprising a memory cell array area and a connection area, wherein the connection area is adjacent to the memory cell array area in a first horizontal direction parallel to an upper surface of the semiconductor substrate;
a first structure on the memory cell array area and the connection area;
a second structure on the first structure in a vertical direction perpendicular to the upper surface of the semiconductor substrate;
a third structure on the second structure in the vertical direction;
a vertical memory structure disposed on the memory cell array area, wherein the vertical memory structure extends in the vertical direction and penetrates the first structure, the second structure, and the third structure; and
a plurality of gate contact plugs disposed on the connection area, wherein the plurality of gate contact plugs extend in the vertical direction and penetrate the first structure, the second structure, and the third structure,
wherein the first structure comprises:
a first stack structure comprising a plurality of first insulating layers and a plurality of first gate wiring layers, which are alternately stacked on each other in the vertical direction; and
a first buffer capping pattern penetrating at least a portion of the first stack structure,
wherein the second structure comprises:
a second stack structure comprising a plurality of second insulating layers and a plurality of second gate wiring layers, which are alternately stacked on each other in the vertical direction;
a second pad capping pattern penetrating at least a portion of the second stack structure; and
a second buffer capping pattern penetrating at least a portion of the second stack structure and connected to the second pad capping pattern,
wherein the third structure comprises:
a third stack structure comprising a plurality of third insulating layers and a plurality of third gate wiring layers, which are alternately stacked on each other in the vertical direction; and
a third pad capping pattern penetrating at least a portion of the third stack structure,
wherein the plurality of second gate wiring layers comprise a plurality of second gate pads covered by the second pad capping pattern,
wherein the plurality of third gate wiring layers comprise a plurality of third gate pads covered by the third pad capping pattern,
wherein at least a portion of the second pad capping pattern overlaps the first buffer capping pattern in the vertical direction, and
wherein at least a portion of the third pad capping pattern overlaps the second buffer capping pattern in the vertical direction.

15. The semiconductor device according to claim 14,
wherein the first structure comprises a first upper pad capping pattern and a first lower pad capping pattern,
the second structure comprises a second upper pad capping pattern and a second lower pad capping pattern,
the third structure comprises a third upper pad capping pattern and a third lower pad capping pattern,
the second pad capping pattern is the second lower pad capping pattern, and
the third pad capping pattern is the third lower pad capping pattern.

16.-17. (canceled)

18. The semiconductor device according to claim 15,
wherein, when viewed in a plan view, the first upper pad capping pattern and the second upper pad capping pattern abut each other, and the second upper pad capping pattern and the third upper pad capping pattern abut each other.

19. The semiconductor device according to claim 18,
wherein the connection area comprises first to sixth regions disposed in the first horizontal direction away from the memory cell array area,
wherein the third upper pad capping pattern is disposed in the first region,
the second upper pad capping pattern is disposed in the second region,
the first upper pad capping pattern is disposed in the third region,
the second buffer capping pattern and the third lower pad capping pattern are disposed in the fourth region,
the first buffer capping pattern and the second lower pad capping pattern are disposed in the fifth region, and
the first lower pad capping pattern is disposed in the sixth region.

20. An electronic system comprising:
a main substrate;
a semiconductor device on the main substrate; and
a controller disposed on the main substrate and electrically connected to the semiconductor device,
wherein the semiconductor device comprises:
a semiconductor substrate comprising a memory cell array area and a connection area, wherein the connection area is adjacent to the memory cell array area in a first horizontal direction parallel to an upper surface of the semiconductor substrate;
a first stack structure disposed on the upper surface of the semiconductor substrate and comprising a plurality of first insulating layers and a plurality of first gate layers, which are alternately stacked on each other in a vertical direction perpendicular to the upper surface of the semiconductor substrate and disposed on the memory cell array area and the connection area, the first stack structure comprising a first recess area disposed on the connection area;
a second stack structure disposed on the first stack structure and comprising a plurality of second insulating layers and a plurality of second gate layers, which are alternately stacked on each other, the second stack structure comprising a second recess area disposed on the connection area;
a first capping pattern disposed on the first recess area;
a second capping pattern disposed on the second recess area, wherein the first recess area comprises a first gate pad area and a first planar area which are integrally formed with each other, the second recess area comprises a second gate pad area, and at least a portion of the second gate pad area overlaps the first planar area in the vertical direction; and
a plurality of gate contact plugs extending lengthwise in the vertical direction and penetrating the first planar area of the first recess area and the second gate pad area.

21. The semiconductor device according to claim 15, wherein the connection area comprises first to sixth regions disposed in a direction away from the memory cell array area,
the second pad capping pattern and the first buffer capping pattern are disposed in the fourth region, and
the third pad capping pattern and the second buffer capping pattern are disposed in the fifth region.

22. The semiconductor device according to claim 15, wherein the connection area comprises first to sixth regions disposed in a direction away from the memory cell array area,
the second pad capping pattern and the first buffer capping pattern are disposed in the fifth region, and
the third pad capping pattern and the second buffer capping pattern are disposed in the fourth region.
